(19) United States
(12) Patent Application Publication
(10) Pub. No.: US 2013/0101925 A1
(43) Pub. Date: Apr. 25, 2013

(54) RETICLE FOR EXPOSURE, EXPOSURE METHOD AND PRODUCTION METHOD OF SEMICONDUCTOR WAFER

(71) Applicant: SHARP KABUSHIKI KAISHA, Osaka-shi (JP)

(72) Inventor: Hironobu SHIMIZU, Osaka-shi (JP)

(73) Assignee: SHARP KABUSHIKI KAISHA, Osaka (JP)

(21) Appl. No.: 13/625,207

(22) Filed: Sep. 24, 2012

(30) Foreign Application Priority Data
Sep. 22, 2011 (JP) 2011-208171
Feb. 6, 2012 (JP) 2012-23454

(51) Int. Cl. G03F 1/00

(52) U.S. Cl. CPC G03F 1/00
USPC 430/5; 430/322; 430/319

(57) ABSTRACT

A reticle comprises a reticle pattern comprising a plurality of chip patterns in a circular effective exposure region of a reduced projection exposure apparatus. The reticle pattern has an outer shape arranged to be inscribed in or without jutting out from a circle of the effective exposure region with a greater number of chip patterns in comparison to the number of chip patterns in a quadrangular shape in a plane view, and when sequentially exposed. The plurality of chip patterns are arranged such that a top part of the reticle pattern fits in without space to a bottom position of the reticle patterns adjacent to each other to the left and right. An exposure method using the reticle and a production method of a semiconductor wafer are also provided.

This nonprovisional application claims priority under 35 U.S.C. §119(a) to Patent Application No. 2011-208171 filed in Japan on Sep. 22, 2011, and No. 2012-023454 filed in Japan on Feb. 6, 2012, the entire contents of which are hereby incorporated by reference.

### TECHNICAL FIELD

The present inventions relate to a reticle for exposure that is used for a stepper apparatus and the like as a reduced projection exposure apparatus for use in production of a semiconductor apparatus such as a semiconductor integrated circuit (IC, LSI, and the like), light-emitting apparatus such as LED and laser, or a solid-state imaging element; an exposure method of exposure using said reticle for exposure; and a production method of a semiconductor wafer for producing a plurality of semiconductor apparatuses using said exposure method.

### BACKGROUND ART

Conventionally, for production of a semiconductor apparatus such as a semiconductor integrated circuit or a solid-state imaging element, a so-called stepper exposure method is known, wherein numerous integrated circuit patterns are accurately exposed on a wafer, on which a photoresist film is formed, by repeatedly performing reduced projection exposure with a stepper apparatus while changing positions such that chip patterns are adjacent to each other, by using a reticle (photomask) on which chip patterns that is about 5 to 10 times the size of a chip to be produced are formed.

A conventional exposure method using such a reticle for exposure is disclosed in Patent Literature 1, and will be described in detail using FIGS. 28(a), 28(b), 29(a), and 29(b).

FIG. 28 is an explanatory view of an exposure method using a conventional reticle for reduced projection exposure disclosed in Patent Literature 1. FIG. 28(a) is a plane view illustrating a relationship between a reticle pattern and an effective exposure region. FIG. 28(b) is a diagram of sequential exposure patterns to a wafer.

As illustrated in FIGS. 28(a) and 28(b), in a conventional exposure method, reduced projection exposure is performed sequentially on a surface of a wafer, on which a photo resist film is formed, using a reticle formed such that a square reticle pattern 102 having four chip patterns 101 is inscribed in an effective exposure region 103, which is a high resolution region. In a conventional reticle, since a square reticle pattern 102 is used, a chip pattern 101 cannot be accommodated any more even if the area of the effective exposure region 103 has more space.

Chip patterns 101 are made sequentially through reduced projection exposure on a wafer 104, on which a photoresist film is formed, by using a reticle having a square reticle pattern 102 having four chip patterns 101.

In FIG. 29(a), a chip pattern of a reticle mounted with four chip patterns which juts out from the wafer 104 of FIG. 28(b) is indicated with an “x”. In order to complete an exposure of fifty-two chip patterns that can be formed on the wafer 104, on which a photoresist film is formed, a total of sixteen shots are required: twelve shots for which all four chip patterns 101 of a reticle are effective; and additional four shots in the four corners for which one chip pattern 101A of the four chip patterns 101 of a reticle is effective.

In this case, in order to shorten the time required for an exposure process of the wafer 104 and to minimize the deviation of an alignment to improve the yield rate, reducing the number of shots required to expose chip patterns 101 on the entire surface of the wafer 104, on which a photo resist film is formed, is strongly desired.

In FIG. 29(b), a chip pattern jutting out from the wafer 104 when the wafer accommodation efficiency is raised by offsetting is indicated with an “x”. In order to raise the exposure efficiency by offsetting and to complete an exposure of fifty-two chip patterns that can be formed on the wafer 104, on which a photo resist film is formed, ten shots for which all of the four chip patterns 101 of a reticle are effective and additional four shots in the four corners for which three chip patterns 101A of the four chip patterns 101 of a reticle are effective, for a total of fourteen shots, are required.

FIG. 30 is a plane view illustrating another example of a conventional exposure method using a reticle for exposure disclosed in Patent Literature 1. FIG. 30(a) is a plane view illustrating the relationship between a reticle pattern and an effective exposure region. FIG. 30(b) is a diagram of sequential exposure patterns to a wafer.

As illustrated in FIGS. 30(a) and 30(b), in the conventional exposure method, reduced projection exposure is sequentially performed on a surface of a wafer 204, on which a photo resist film is formed, using a reticle formed such that a cross-shaped reticle pattern 202 having five chip patterns 201 is inscribed in an effective exposure region 203, which is a high resolution region.

In this manner, if chip patterns 201 are arranged in a cross shape, five chip patterns 201 can be formed in the effective exposure region 203 with one shot. This is more efficient in comparison to a case of FIG. 28(a) in which four chip patterns 101 are formed with one shot.

As illustrated in FIG. 31, thirty five chips can be exposed by seven shots for which all of the five chip patterns 201 of a reticle are effective; with an additional shot for which four out of the five chip patterns 201 of a reticle are effective for a total of eight shots, a total of thirty nine chips can be exposed; with two additional shots for which three of the five chip patterns 201 of a reticle are effective for a total of ten shots, a total of forty five chips can be exposed; with two additional shots for which two of the five chip patterns 201 of a reticle are effective for a total of twelve shots, a total of forty nine chips can be exposed; and with three additional shots for which one of five chip patterns 201 of a reticle is effective for a total of fifteen shots, a total of fifty two chips can be exposed.

### CITATION LIST

### Patent Literature

Patent Literature 1: Japanese Laid-Open Publication No. 5-335203

### SUMMARY OF THE INVENTION

### Technical Problem

In the conventional exposure method disclosed in Patent Literature 1, in FIG. 29(a), there is a problem of not being able to utilize a high resolution area at maximum efficiency, when a plurality of chip patterns 101 are arranged in a rectangular shape in a reticle as reticle pattern 102 so as to facilitate a sequential arrangement of reticle patterns 102 on the wafer 104; an effective exposure region 103, which is high resolution region, is circular; and reticle pattern 102 is arranged in a size of an inscribed rectangle. If there are only a few chip patterns on the reticle pattern 102, the number of shots for exposure increases and the throughput declines.

The shot efficiency of the reticle mounted with four chip patterns of FIG. 29(a) is 52 chips/16 shots=3.25, and there are twelve loss chips jutting out from the wafer 204. Further, the shot efficiency of the reticle mounted with four chip patterns by offsetting of FIG. 29(b) is 52 chip patterns/14 shots=3.7, and there are four loss chips jutting out from the wafer 204. Furthermore, the shot efficiency of the reticle mounted with five chip patterns of FIG. 31, for which the number of chip patterns are increased, is 52 chip patterns/15 shots=3.47, which exposes seventy five chip patterns in fifteen shots, but loss chips jutting out from the wafer 204 reaches 23 chip patterns.

The number of shots is decreased and throughput is improved by increasing the number of chip patterns within a reticle pattern, from the reticle mounted with four chip patterns of FIG. 29(a) to the reticle mounted with five chip patterns of FIG. 31. In FIG. 31, fifty two chip patterns are drawn with fifteen shots. Since the shot arrangement to the wafer 204 is in a cross shape and is not in a parallel manner, numerous loss chip patterns have occurred at the peripheral edge section. Specifically, for ordinary reticles arranged in a rectangle, sixteen shots are needed when the reticles are directly arranged in length and width directions. However, in view of the fact that fifty two chip patterns can be realized with fourteen shots by offsetting as in FIG. 29(b), it can be thought that the cross-shaped reticle mounted with five chip patterns illustrated in FIG. 31 has low shot efficiency in comparison to the reticle mounted with four chip patterns of FIG. 29(b), thus does not have any advantage. Furthermore, the cross-shaped reticle mounted with five chip patterns that is illustrated in FIG. 31 had a problem of step feeding becoming extremely complicated to fit the shapes in without space when step feeding is used to sequentially expose the wafer 204 due to the cross shape.

The present invention is intended to solve the conventional problems described above. It is an objective of the present invention to provide a reticle for utilizing a high resolution region efficiently and improving throughput by increasing the number of chip patterns for each shot and fitting in reticle patterns with each other with no space without complicating the step feeding; an exposure method using said reticle; and a production method of a semiconductor wafer for producing a semiconductor wafer using said exposure method.

### Solution to Problem

A reticle for exposure according to the present invention containing a reticle pattern constituted of a plurality of chip patterns in a circular effective exposure region of a reduced projection exposure apparatus is provided, where the reticle pattern has an outer shape arranged to be inscribed in or without jutting out from the circle of the effective exposure region with a greater number of chip patterns in comparison to the number of chip patterns in a quadrangular shape in a plane view, and when sequentially exposed, the plurality of chip patterns are arranged such that a top part of the reticle pattern fits in without space to a bottom position of the reticle patterns adjacent to each other to the left and right, thereby achieving an objective described above.

Preferably, in a reticle for exposure according to the present invention, the outer shape of the reticle pattern has the plurality of chip patterns arranged in a stair-like shape of a shot with uniform steps or uneven steps, such that the outer shape of the reticle pattern is inscribed in or does not jut out from the circle of the effective exposure region.

Still preferably, in a reticle for exposure according to the present invention, the outer shape of the reticle pattern has the plurality of chip patterns arranged line-symmetrically top and bottom or left and right in a plane view with respect to a mid line along a scribe line between the chip patterns.

Still preferably, in a reticle for exposure according to the present invention, the outer shape of the reticle pattern has the plurality of chip patterns arranged line-symmetrically top and bottom and left and right in a plane view with respect to a mid line along a scribe line between the chip patterns.

Still preferably, in a reticle for exposure according to the present invention, the outer shape of the reticle pattern has the plurality of chip patterns arranged point-symmetrically.

Still preferably, in a reticle for exposure according to the present invention, the outer shape of the reticle pattern has the plurality of chip patterns arranged asymmetrically.

Still preferably, in a reticle for exposure according to the present invention, one side of a quadrangular shape in a plane view of the chip patterns and another side adjacent thereto are equal or different.

Still preferably, in a reticle for exposure according to the present invention, when m and n are both integers greater than or equal to four, the reticle pattern has a plurality of chip patterns resulting from taking away chip patterns of four corners from a plurality of chip patterns with an m×n quadrangular shape.

Still preferably, in a reticle for exposure according to claim 1, wherein when m and n are both integers greater than or equal to two, the reticle pattern has an even number of chip patterns protruding out to the top and bottom or/and the left and right from the entire side or from each center section of four sides of chip patterns with an m×n quadrangular shape.

Still preferably, in a reticle for exposure according the present invention, when m and n are both four, the reticle pattern has twelve chip patterns resulting from taking away chip patterns of four corners from 4×4 or sixteen chip patterns.

Still preferably, in a reticle for exposure according to the present invention, when m and n are both two, the reticle pattern has chip patterns protruding out from the entire side of four sides of a reticle pattern constituted of 2×2 or four chip patterns, with two chip patterns each protruding out to the top and bottom and two chip patterns each protruding out to the left and right.

Still preferably, in a reticle for exposure according to the present invention, when m and n are both integers greater than or equal to six, the reticle pattern has a plurality of chip patterns resulting from taking away one or a plurality of chip patterns in four corners and those adjacent to the four corners from a plurality of chip patterns with an m×n quadrangular shape.

Still preferably, in a reticle for exposure according to the present invention, when m and n are both six, the reticle pattern has twenty-four chip patterns resulting from taking away each of three chip patterns in four corners and in four corner sections adjacent to the four corners from 6×6 or thirty six chip patterns.

Still preferably, in a reticle for exposure according to the present invention, when m and n are both four, the reticle pattern has chip patterns protruding out from each center section of four sides of a reticle pattern constituted of 4×4 or sixteen chip patterns, with two chip patterns each protruding out from the top and bottom and two chip patterns each protruding out from the left and right.

Still preferably, in a reticle for exposure according to the present invention, when m and n are both integers greater than or equal to eight, the reticle pattern has a plurality of chip patterns resulting from taking away each chip patterns of four corner sections, in four corners and one or a plurality of consecutive chip patterns adjacent the four corners inside and on the outer circumference, from a plurality of chip patterns with an m×n quadrangular shape such that the reticle pattern is inscribed in or does not jut out from the circle in the effective exposure region.

Still preferably, in a reticle for exposure according to the present invention, when m and n are both integers greater than or equal to six, the reticle pattern has one or a plurality of chip patterns taken away in the up and down directions in four corners of chip patterns with an m×n quadrangular shape and has an even number of chip patterns protruding out to the top and bottom or/and left and right from each center section of four sides of chip patterns with the m×n quadrangular shape, such that the reticle pattern is inscribed in or does not jut out from the circle of the effective exposure region.

Still preferably, in a reticle for exposure according to the present invention, when m and n are both eight, the reticle pattern has forty chip patterns resulting from taking away each six chip patterns of four corner sections, in four corners and one or a plurality of consecutive chip patterns adjacent the four corners inside and on the outer circumference, from 8×8 or sixty four chip patterns.

Still preferably, in a reticle for exposure according to the present invention, when m and n are both six, the reticle pattern has each chip pattern of four corners taken away from a reticle pattern constituted of 6×6 or thirty-six chip patterns and chip patterns protrude out from each center section of four sides of the reticle pattern constituted of the 6×6 or thirty-six chip patterns, with two chip patterns each protruding out to the top and bottom and two chip patterns each protruding out to the left and right.

Still preferably, in a reticle for exposure according to the present invention, when m is eight and n is nine, the reticle pattern has forty-eight chip patterns resulting from taking away each six chip patterns of four corner sections, in four corners and one or a plurality of consecutive chip patterns adjacent the four corners inside and on the outer circumference, from 8×9 or seventy-two chip patterns.

Still preferably, in a reticle for exposure according to the present invention, when m is six and n is seven, the reticle pattern has each chip pattern in four corners taken away from a reticle pattern constituted of 6×7 or forty-two chip patterns and chip patterns protrude out from each center section of four sides of the reticle pattern constituted of 6×7 or forty-two chip patterns, with two chip patterns each protruding out from the top and bottom and three chip patterns each protruding out to the left and right.

Still preferably, in a reticle for exposure according to the present invention, when m is eight and n is eighteen, the reticle pattern has ninety-six chip patterns resulting from taking away twelve chip patterns each of four corner sections, in four corners and one or a plurality of consecutive chip patterns adjacent the four corners inside and on the outer circumference, from 8×18 or one-hundred-forty-four chip patterns.

Still preferably, in a reticle for exposure according to the present invention, when m is six and n is fourteen, the reticle pattern has two chip patterns each consecutively in the up and down direction of four corners taken away from a reticle pattern constituted of 6×14 or eighty-four chip patterns and chip patterns protruding out from each center section of four sides of the reticle constituted of the 6×14 or eighty-four chip patterns, with two chip patterns with a width of two for a total of four chip patterns each protruding out to the top and bottom, and six chip patterns each protruding out to the left and right.

Still preferably, in a reticle for exposure according to the present invention, when m is eight and n is seventeen or eighteen, the reticle pattern has ninety-six or one-hundred-four chip patterns resulting from taking away each ten chip patterns of four corner sections, in four corners and one or a plurality of consecutive chip patterns adjacent the four corners inside and on the outer circumference, from 8×17 or 8×18, or one-hundred-thirty-six or one-hundred-forty-four chip patterns.

Still preferably, in a reticle for exposure according to the present invention, when m is six and n is fourteen, the reticle pattern has three chip patterns consecutively in the up and down directions in each of the up and down directions of four corners taken away from a reticle pattern constituted of 6×15 or 6×16, or ninety or ninety-six chip patterns and chip patterns protrude out from each center section of four sides of the reticle pattern constituted of 6×15 or 6×16, or ninety or ninety-six chip patterns, with two chip patterns each protruding out to the top and bottom, and seven or eight chip patterns each protruding out to the left and right.

Still preferably, in a reticle for exposure according to the present invention, one or a plurality of evaluation patterns are disposed in place of a region of one or a plurality of chip patterns constituting the reticle pattern.

Still preferably, in a reticle for exposure according to the present invention, one or a plurality of evaluation patterns are disposed inside or outside of an exposure region of the reticle pattern.

Still preferably, in a reticle for exposure according to the present invention, the outer shape of the reticle pattern has a uniform or uneven stair-like shape, and the one or the plurality of evaluation patterns are disposed in a region of chip patterns comprising at least one of a left edge section, a right edge section, a top edge section, or a bottom edge section of the reticle pattern.

Still preferably, in a reticle for exposure according to the present invention, the evaluation pattern is one of a test chip pattern, an alignment pattern, or a pattern for inspection of dimension.

An exposure method according to the present application is provided for repeatedly reduce-exposing adjacent a scribe line on a wafer on which a photoresist film is formed, using a reticle for exposure according to the present invention, such that the reticle patterns fit in with each other without space and the scribe line is positioned between the chip patterns, thereby achieving an objective described above.

Preferably, in an exposure method according to the present invention, the method uses a reticle for exposure provided with the evaluation pattern outside of an exposure region of the reticle pattern and comprises the steps of: shielding a part of a stair-like step section including a top edge part or a bottom edge part of the reticle pattern with a blind function of a stepper to expose the rest of the reticle pattern; and shielding all of the reticle pattern with the blind function of the stepper to expose the evaluation pattern to be adjacent the exposed reticle pattern.

Still preferably, in an exposure method according to the present invention, the method uses a reticle for exposure provided with the evaluation pattern outside of an exposure region of the reticle pattern and comprises the steps of: shielding the reticle pattern with a light shield plate to expose only the evaluation pattern on a predetermined position of a wafer; and shielding the evaluation pattern and an entire region of chip patterns including at least one of a left edge section, a right edge section, a top edge section, or a bottom edge section adjacent to the evaluation pattern with the light shield plate to expose the rest of the reticle pattern on a predetermined position adjacent to the previously exposed evaluation pattern.

Still preferably, in an exposure method according the present invention, the method uses a reticle for exposure provided with the evaluation pattern outside of an exposure region of the reticle pattern and comprises the steps of: shielding the evaluation pattern and the entire region of chip patterns including at least one of the left edge section, the right edge section, the top edge section, or the bottom edge section adjacent to the evaluation pattern with the light shield plate to expose the rest of reticle patterns; and unshielding only the evaluation pattern with the light shield plate to expose the evaluation pattern to chip patterns for the evaluation pattern.

A production method according to the present invention of a semiconductor wafer is provided for producing a plurality of semiconductor elements by pattering the photoresist film using the exposure method according the present invention to form each layer by using the patterned photoresist film as a mask, thereby achieving an objective described above.

The functions of the present invention having the structures described above will be described hereinafter.

According to the present invention, in a reticle for exposure containing a reticle pattern constituted of a plurality of chip patterns in a circular effective exposure region of a reduced projection exposure apparatus, the reticle pattern has an outer shape with a greater number of chip patterns in comparison to the number of chip patterns in a quadrangular shape in a plane view, such that the reticle pattern is inscribed in or does not jut out from a circle of the effective exposure region, and when sequentially exposed, the plurality of chip patterns are arranged such that the top part of the reticle pattern fits in without space to the bottom position of reticle patterns adjacent to each other to the left and right.

Thereby, utilizing the effective exposure region in a most effective manner and improving throughput are made possible by increasing the number of chip patterns per shot and fitting in reticle patterns with each other with no space without complicating the step feeding when sequentially exposed.

When one or a plurality of evaluation patterns are to be disposed in place of a region of one or a plurality of chip patterns constituting a reticle pattern, reduction in the number of chip patterns can be minimized, thus utilizing the effective exposure region in a most effective manner and improving throughput are possible.

### Advantageous Effects of Invention

According to the present invention described above, a reticle pattern has an outer shape of a reticle pattern arranged to the maximum degree has a greater number of chip patterns in comparison to the number of chip patterns in a quadrangular shape in a plane view, such that the reticle pattern is inscribed in or does not jut out from a circle of an effective exposure region and, when sequentially exposed, a plurality of chip patterns are arranged such that the top part of a reticle pattern fits into the bottom position of reticle patterns adjacent to each other to the left and right without space. Thus, utilizing the high resolution region in a most effective manner and improving throughput are made possible by increasing the number of chip patterns per shot and fitting in reticle patterns with each other with no space without complicating the step feeding.

Further, even if one or a plurality of evaluation patterns are disposed in place of a region of one or a plurality of chip patterns constituting a reticle pattern, reduction in the number of chip patterns can be minimized, thus utilizing an effective exposure region in a most effective manner and improving throughput are possible.

These and other advantages of the present invention will become apparent to those skilled in the art upon reading and understanding the following detailed description with reference to the accompanying figures.

### BRIEF DESCRIPTION OF THE DRAWINGS

FIG. 1 is a schematic configuration view illustrating an example of a stepper apparatus in Embodiment 1 of the present invention.

FIG. 2 is an explanatory diagram of Embodiment 1 of an exposure method using a reticle for exposure of FIG. 1. FIG. 2(a) is a plane view illustrating the relationship between a reticle pattern and an effective exposure region. FIG. 2(b) is a diagram of sequential exposure patterns to a wafer.

FIG. 3 is an explanatory diagram of an exposure method using a conventional reticle for exposure as a comparative example of FIG. 2. FIG. 3(a) is a plane view illustrating the relationship between a reticle pattern and an effective exposure region. FIG. 3(b) is a diagram of sequential exposure patterns to a wafer.

FIG. 4 is an explanatory diagram of Embodiment 2 of an exposure method using a reticle for exposure of FIG. 1. FIG. 4(a) is a plane view illustrating the relationship between a reticle pattern and an effective exposure region. FIG. 4(b) is a diagram of sequential exposure patterns to a wafer.

FIG. 5 is an explanatory diagram of an exposure method using a conventional reticle for exposure as a comparative example of FIG. 4. FIG. 5(a) is a plane view illustrating the relationship between a reticle pattern and an effective exposure region. FIG. 5(b) is a diagram of sequential exposure patterns to a wafer.

FIG. 6 is an explanatory diagram of Embodiment 3 of an exposure method using a reticle for exposure of FIG. 1. FIG. 6(a) is a plane view illustrating the relationship between a reticle pattern and an effective exposure region. FIG. 6(b) is a diagram of sequential exposure patterns to a wafer.

FIG. 7 is an explanatory diagram of an exposure method using a conventional reticle for exposure as a comparative example of FIG. 6. FIG. 7(a) is a plane view illustrating the relationship between a reticle pattern and an effective exposure region. FIG. 7(b) is a diagram of sequential exposure patterns to a wafer.

FIG. 8 is an explanatory diagram of Embodiment 4 of an exposure method using a reticle for exposure of FIG. 1. FIG. 8(a) is a plane view illustrating the relationship between a reticle pattern and an effective exposure region. FIG. 8(b) is a diagram of sequential exposure patterns to a wafer 4.

FIG. 9 is an explanatory diagram of Embodiment 5 of an exposure method using a reticle for exposure of FIG. 1. FIG. 9(a) is a plane view illustrating the relationship between a reticle pattern and an effective exposure region. FIG. 9(b) is a diagram of sequential exposure patterns to a wafer.

FIG. 10 is an explanatory diagram of Embodiment 6 of an exposure method using a reticle for exposure of FIG. 1. FIG. 10(a) is a plane view illustrating the relationship between a reticle pattern and an effective exposure region. FIG. 10(b) is a diagram of sequential exposure patterns to a wafer.

FIG. 11(a) is a plane view illustrating the relationship between a reticle pattern per shot by a conventional exposure method and an effective exposure region. FIG. 11(b) is a plane view illustrating the relationship between a reticle pattern of the above-described Embodiment 5 and an effective exposure region. FIG. 11(c) is a plane view illustrating the relationship between a modified example of a reticle pattern of the above-described Embodiment 6 and an effective exposure region.

FIG. 12 is an explanatory diagram of Embodiment 7 of an exposure method using a reticle for exposure of FIG. 1. FIG. 12(a) is a plane view illustrating the relationship between a reticle pattern and an effective exposure region. FIG. 12(b) is a diagram of sequential exposure patterns to a wafer 4.

FIGS. 13(a) and 13(b) are explanatory diagrams describing a case where the outer shape of a reticle pattern 82 is asymmetrical.

FIG. 14 is an explanatory diagram of Embodiment 8 of an exposure method using a test chip pattern TEG for one of a plurality of chip patterns of the reticle for exposure 2D of FIG. 9. FIG. 14(a) is a plane view illustrating the relationship between a reticle pattern using a test chip pattern TEG and an effective exposure region. FIG. 14(b) is a diagram of sequential exposure patterns to a wafer 4.

FIG. 15 is an explanatory diagram of an exposure method using a conventional reticle for exposure as a comparative example of FIG. 14. FIG. 15(a) is a plane view illustrating the relationship between a reticle pattern and an effective exposure region. FIG. 15(b) is a diagram of sequential exposure patterns to a wafer.

FIG. 16 is an explanatory diagram of Embodiment 9 of an exposure method using a test chip pattern TEG on a four chip pattern in the top edge section of a plurality of chip patterns of the reticle for exposure 2D of FIG. 9. FIG. 16(a) is a plane view illustrating the relationship between a reticle pattern using a test chip pattern TEG and an effective exposure region. FIG. 16(b) is a diagram of sequential exposure patterns to a wafer 4.

FIGS. 17(a) to 17(c) are explanatory diagrams for describing an exposure method using the reticle for exposure of FIG. 16 using a test chip pattern TEG.

FIG. 18 is an explanatory diagram of an exposure method using a conventional reticle for exposure as a comparative example of FIG. 16. FIG. 18(a) is a plane view illustrating the relationship between a reticle pattern and an effective exposure region. FIG. 18(b) is a diagram of sequential exposure patterns to a wafer.

FIGS. 19(a) to 19(c) are explanatory diagrams for describing an exposure method using the conventional reticle for exposure of FIG. 18 using a test chip pattern TEG.

FIG. 20(a) is a plane view illustrating the relationship between a reticle pattern per shot by a conventional exposure method with respect to the above-described Embodiment 9 using a test chip pattern TEG and an effective exposure region. FIG. 20(b) is a plane view illustrating the relationship between the reticle pattern of the above-described Embodiment 8 using a test chip pattern TEG and an effective exposure region. FIG. 20(c) is a plane view illustrating the relationship between a case where a test chip pattern TEG is used as one of a plurality of chip patterns in a modified example of the reticle pattern of the above-described Embodiment 6 using a test chip pattern TEG and an effective exposure region.

FIG. 21 is an explanatory diagram of a modified example of Embodiment 6 of an exposure method using a reticle for exposure 2E′ of FIG. 1 using a test chip pattern TEG. FIG. 21(a) is a plane view illustrating the relationship between a reticle pattern and an effective exposure region. FIG. 21(b) is a diagram of sequential exposure patterns to a wafer.

FIG. 22 is an explanatory diagram of a modified example of Embodiment 6 of an exposure method using a reticle for exposure 2E′ of FIG. 1 using a test chip pattern TEG. FIG. 22(a) is a plane view illustrating the relationship between a reticle pattern and an effective exposure region. FIG. 22(b) is a diagram of sequential exposure patterns to a wafer.

FIG. 23 is an explanatory diagram of a modified example of Embodiment 7 of an exposure method using a reticle for exposure 2F′ of FIG. 1 using a test chip pattern TEG. FIG. 23(a) is a plane view illustrating the relationship between a reticle pattern and an effective exposure region. FIG. 23(b) is a diagram of sequential exposure patterns to a wafer 4.

FIG. 24 is an explanatory diagram of a modified example of Embodiment 1 of an exposure method using a reticle for exposure 2′ of FIG. 1 using a test chip pattern TEG. FIG. 24(a) is a plane view illustrating the relationship between a reticle pattern and an effective exposure region. FIG. 24(b) is a diagram of sequential exposure patterns to a wafer.

FIG. 25 is an explanatory diagram of a modified example of Embodiment 2 of an exposure method using a reticle for exposure 2A′ of FIG. 1 using a test chip pattern TEG. FIG. 25(a) is a plane view illustrating the relationship between a reticle pattern and an effective exposure region. FIG. 25(b) is a diagram of sequential exposure patterns to a wafer.

FIG. 26 is an explanatory diagram of a modified example of Embodiment 3 of an exposure method using a reticle for exposure 2B′ of FIG. 1 using a test chip pattern TEG. FIG. 26(a) is a plane view illustrating the relationship between a reticle pattern and an effective exposure region. FIG. 26(b) is a diagram of sequential exposure patterns to a wafer.

FIG. 27 is an explanatory diagram of a modified example of Embodiment 4 of an exposure method using a reticle for exposure 2C′ of FIG. 1 using a test chip pattern TEG. FIG. 27(a) is a plane view illustrating the relationship between a reticle pattern and an effective exposure region. FIG. 27(b) is a diagram of sequential exposure patterns to a wafer.

FIG. 28 is an explanatory diagram of an exposure method using a conventional reduced projection exposure method disclosed in Patent Literature 1. FIG. 28(a) is a plane view illustrating the relationship between a reticle pattern and an effective exposure region. FIG. 28(b) is a diagram of sequential exposure patterns to a wafer.

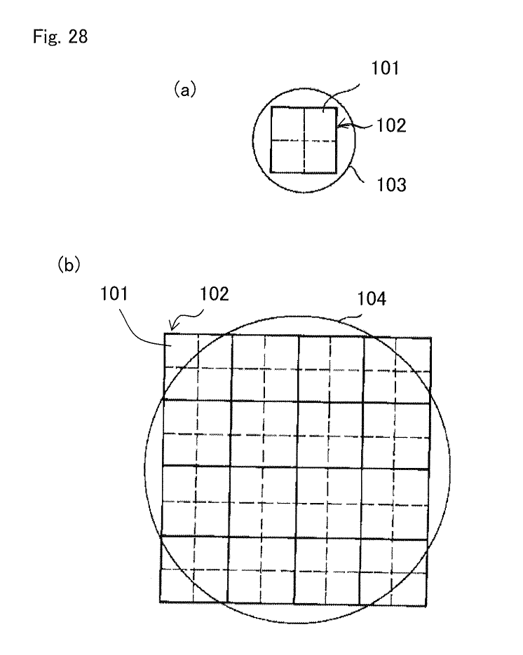

FIG. 29(a) is a plane view indicating an “x” for a chip pattern of a reticle mounted with four chip patterns jutting out from a wafer region of FIG. 28(b). FIG. 29(b) is a plane view indicating an “x” for a chip pattern jutting out from a wafer region when wafer region accommodation rate is increased.

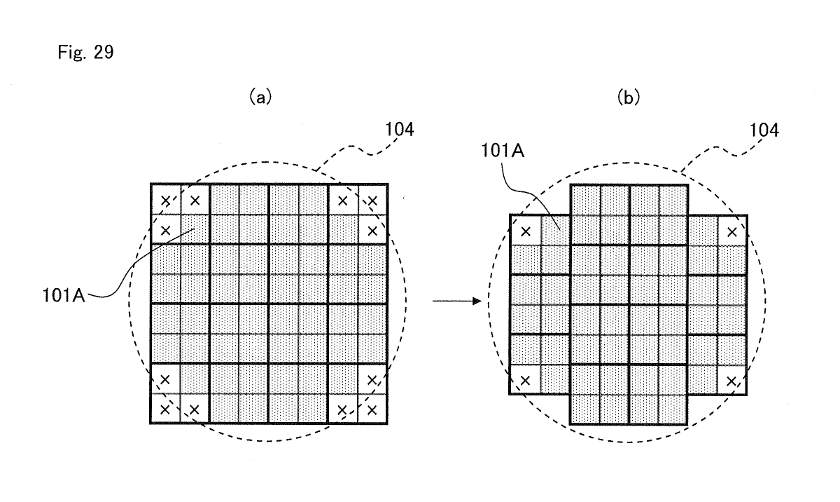

FIG. 30 is a plane view illustrating another example of a conventional exposure method using a reticle for exposure disclosed in Patent Literature 1. FIG. 30(a) is a plane view illustrating the relationship between a reticle pattern and an effective exposure region. FIG. 30(b) is a diagram of sequential exposure patterns to a wafer.

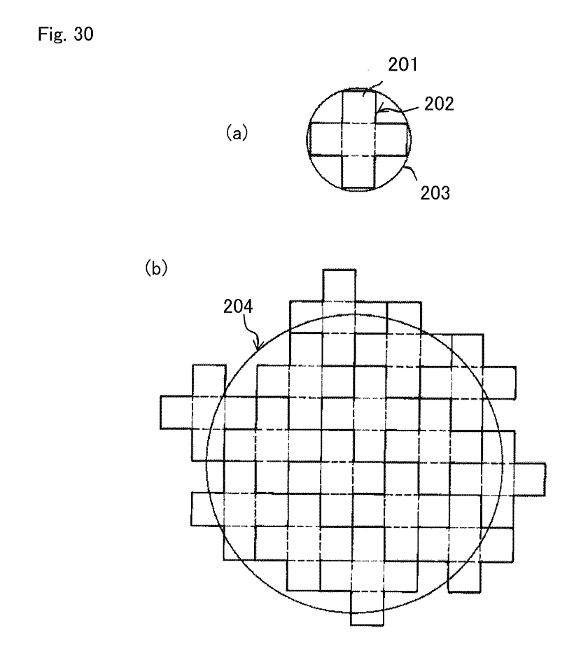

FIG. 31 is a plane view indicating an “x” for a chip pattern of a reticle mounted with five chip patterns jutting out from a wafer region of FIG. 30(b).

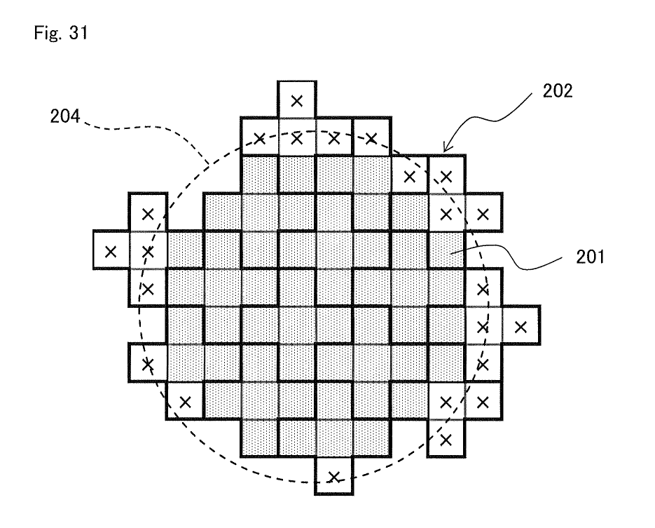

### DESCRIPTION OF THE PREFERRED EMBODIMENTS

Hereinafter, Embodiments 1 to 7 of a reticle for exposure, an exposure method for exposure using said reticle for exposure, and a production method of a semiconductor wafer using said exposure method of the present invention used for a stepper apparatus will be described in detail with reference to the accompanying figures. In view of preparing the figures, each of the thicknesses, lengths or the like of each element in the figures are not limited to those described in the figures.

### Embodiment 1

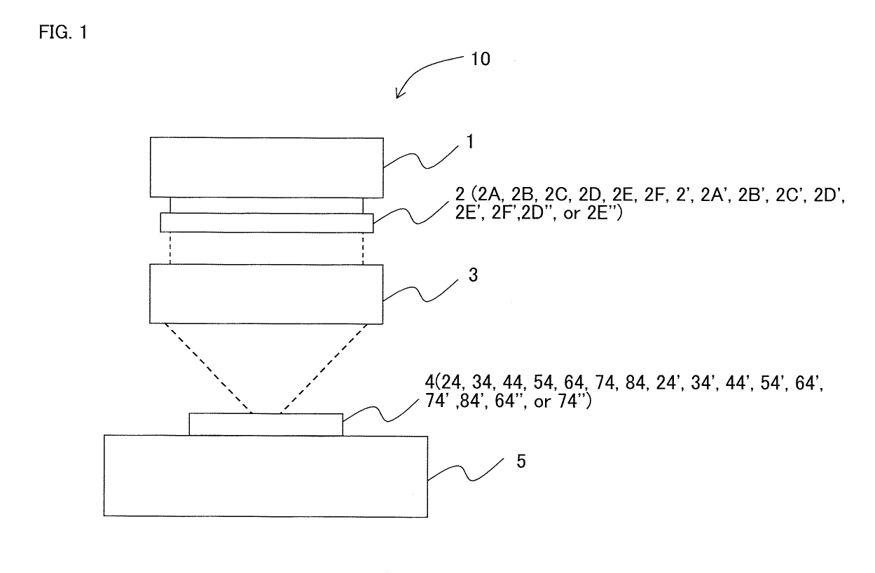

FIG. 1 is a schematic configuration view illustrating an example of a stepper apparatus in Embodiment 1 of the present invention.

In FIG. 1, a stepper apparatus 10 as a reduced projection exposure apparatus of Embodiment 1 comprises: a floodlight apparatus 1 for irradiating a light for exposure downward; a reticle for exposure 2, which is an original plate for exposure (photomask) disposed under the floodlight apparatus 1 and is for performing reduced projection exposure; a reduced projection apparatus 3 for reduce-projecting a reticle pattern of a chip pattern light that goes through the reticle for exposure 2; and a table 5 mounted with a wafer 4 as a semiconductor substrate that is freely movable in the X and Y axis directions, wherein the reticle pattern of the chip pattern light that goes through the reticle for exposure 2 is sequentially exposed on the wafer 4, on which a photoresist film is formed, by moving the wafer 4 with the table 5.

Next, the exposure method of Embodiment 1 repeatedly reduce-exposes adjacent to a scribe line such that the scribe line is positioned at each position between chip patterns on the wafer 4, on which a photoresist film is formed, by using the reticle for exposure 2. Alignment marks are disposed on or in a neighboring location of the scribe line, and reticle patterns are sequentially exposed by determining the position such that the alignment marks match. The repeating of reduced exposure is sequentially lined up in the left and right direction (horizontal direction) of the plane surface of a chip for exposure, and when a row is changed, exposure pitch is offset by a half pitch for sequential exposure.

Further, for the production method of a semiconductor wafer using the exposure method of Embodiment 1, a photoresist film is patterned using the exposure method, and each layer of, for example, a semiconductor integrated circuit (IC, LSI, and the like), a light emitting apparatus such as LED and laser, and a transistor, electrodes, impurities diffusion layer, and the like that constitute a solid-state imaging element and the like is formed as a semiconductor apparatus with the patterned photoresist film as a mask to produce a plurality of semiconductor elements.

A reticle pattern mentioned below of the reticle for exposure 2 of Embodiment 1 is configured line-symmetrically top and bottom and left and right in a plane view along a scribe line between chip patterns such that the reticle pattern is inscribed in or is arranged without jutting out from a circle of an effective exposure region mentioned below to maximize the number of chip patterns arranged, and a plurality of chip patterns are arranged.

The pattern configuration of a reticle pattern mentioned below of Embodiment 1 will now be described in detail.

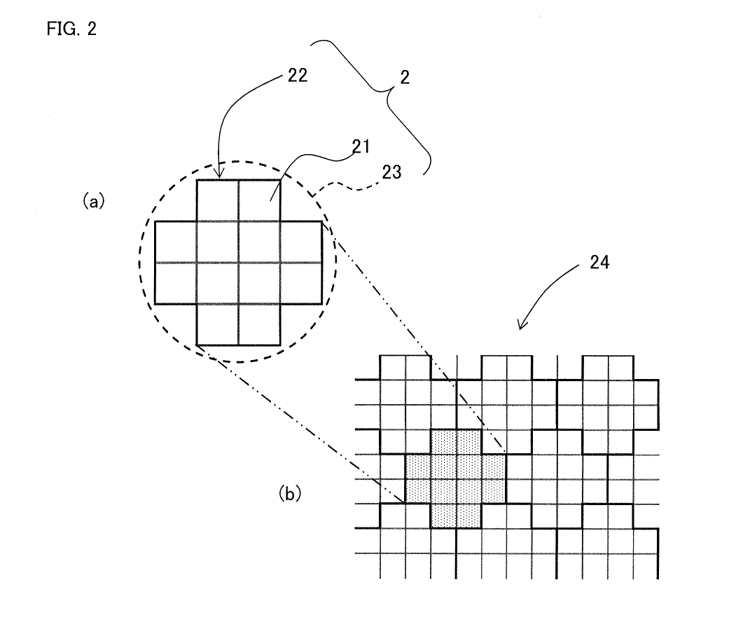

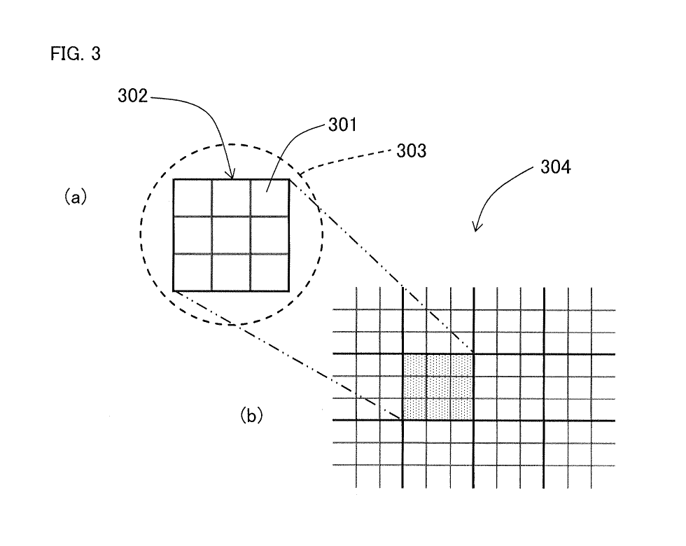

FIG. 2 is an explanatory diagram of Embodiment 1 of an exposure method using the reticle for exposure 2 of FIG. 1. FIG. 2(a) is a plane view illustrating the relationship between a reticle pattern and an effective exposure region. FIG. 2(b) is a diagram of sequential exposure patterns to a wafer 4. FIG. 3 is an explanatory diagram of an exposure method using the conventional reticle for exposure as a comparative example of FIG. 2. FIG. 3(a) is a plane view illustrating the relationship between a reticle pattern and an effective exposure region. FIG. 3(b) is a diagram of sequential exposure patterns to a wafer.

In FIGS. 3(a) and 3(b), in the conventional exposure method, reduced projection exposure is performed sequentially on a surface of a wafer 304, on which a photo resist film is formed, using a reticle for exposure formed such that a square reticle pattern 302 having, for example, 3×3 or nine chip patterns 301 is inscribed in a circle of an effective exposure region 303, which is a high resolution region. In the conventional reticle for exposure, since the square reticle pattern 302 is used, a chip pattern 301 cannot be accommodated any more even if the area of the effective exposure region 303 has more space.

In contrast, in FIGS. 2(a) and 2(b), in an exposure method using the reticle for exposure 2 of Embodiment 1, reduced projection exposure is performed sequentially on a surface of a wafer 24, on which a photoresist film is formed, using the reticle for exposure 2 formed such that a reticle pattern 22 that is line-symmetrical to the top and bottom and left and right having, for example, twelve chip patterns 21 resulting from taking away chip patterns in the four corners of 4×4 or sixteen chip patterns 21. For the line symmetry to the top and bottom and left and right, a line of line-symmetry is positioned along a scribe line (cutting line when chips are made into individual pieces) between chip patterns 21. In the reticle pattern 22, chip patterns 21 protrude out from all four sides of the reticle pattern 22 constituted of 2×2 or four chip patterns 21, with two chip patterns 21 each protruding out to the top and bottom, and also two chip patterns each protruding out to the left and right. In this case, if the reticle pattern 22 of this shape is sequentially exposed on the wafer 24, on which a photoresist film is formed, the reticle pattern 22 is arranged as in FIG. 2(b), with consecutive reticle patterns 22 in the first row and the second row being offset by half a pitch. Specifically, when the reticle patterns 22 that protrude out to the top and bottom for the amount of two chip patterns 21 are sequentially exposed, the reticle patterns 22 form a shape with depressions for the amount of two chip patterns 21 on the top and bottom of the boundary position between the reticle patterns 22. A reticle pattern 22 protruding out for the amount of two chip patterns 21 fits in perfectly with the shape of the depression for the amount of two chip patterns 21. In this manner, in order for the reticle patterns 22 to fit in perfectly in the first row and the second row, the number of chip patters 21 that protrude out needs to be an even number.

In an exposure process for exposing and patterning the photoresist film on the wafer 24 in a predetermined shape, the photoresist film is exposed by using the reticle pattern 22 with a shape and a shot in a stair-like outer shape, instead of a square of a rectangle illustrated in FIGS. 3(a) and 3(b), such that the outer shape is inscribed in or does not jut out from the circle of the effective exposure region 23. As in the arrangement of twelve chip patterns 21 on the reticle for exposure 2, chip patterns 21 are arranged, such that more chip patterns are in the effective exposure region 23 that is a high resolution region. Although the chip size is the same as in the above-described conventional exposure method, the number of chip patterns is increased from nine chip patterns to twelve chip patterns in one shot for exposure. It is not required that the shape of a shot of the reticle pattern 22 is made to be a square or a rectangle in a plane view at this time. At the time of exposure on the wafer 24, a plurality of chip patterns 21 are devised to be arranged in the effective exposure region 23 on the reticle for exposure 2, such that more chip patterns can be arranged without space between each pattern at the time of sequential exposure.

In order to arrange more chip patterns in the effective exposure region 23 on the reticle for exposure 2, the shapes of shots of adjacent reticle patterns 22 are arranged efficiently on the wafer 24 to be repeatedly arranged without space and in a line in the horizontal or vertical directions, by arranging chip patterns 21 in a stair-like outer shape such that more chip patterns 21 are inscribed to the maximum degree in a writing region (effective exposure region 23) and by devising a shot arrangement on the wafer 24.

The reticle pattern 22 is a pattern arranged in a stair-like outer shape such that more chip patterns 21 are inscribed to the maximum degree in a writing region (effective exposure region 23). The reticle pattern 22 is repeatedly arranged with no space between shots and in a line in the horizontal and vertical directions. In other words, the reticle pattern 22 is a plurality of chip patterns 21 of the reticle for exposure 2 and also is a plurality of chip patterns formed by exposure on the resist film on the wafer 24.

From the above, according to Embodiment 1, the reticle pattern 22 has twelve chip patterns 21 wherein chip patterns of the four corners are taken out from 4×4 or 16 chip patterns, or in another point of view, in the reticle pattern 22, chip patterns 21 protrude out from all four sides of the reticle pattern 22 constituted of 2×2 or four chip patterns 21, with two chip patterns 21 each protruding out to the top and bottom and also two chip patterns 21 each protruding out to the left and right.

Thereby, in the conventional exposure method illustrated in FIGS. 3(a) and 3(b), exposure of the reticle pattern 302 constituted of nine chip patterns 301 per shot is possible. However, in the exposure method using the reticle for exposure 2 of Embodiment 1 illustrated in FIGS. 2(a) and 2(b), exposure of the reticle pattern 22 constituted of twelve chip patterns 21 per shot is possible. Thereby, in the exposure method of Embodiment 1, throughput is improved 12/9 times in comparison to the conventional exposure method. In this manner, utilizing the effective exposure region 23 in a most effective manner and improving throughput are made possible by increasing the number of chip patterns per shot and fitting in reticle patterns 22 with each other with no space without complicating the step feeding.

In Embodiment 1, as in FIG. 2, a case is described where the reticle pattern 22 has twelve chip patterns 21 wherein chip patterns of the four corners are taken out from the 4×4 or 16 chip patterns, or in another point of view, a case is described where chip patterns 21 protrude out from all four sides of the reticle pattern 22 constituted of 2×2 or four chip patterns 21, with two chip patterns each protruding out to the top and bottom and also two chip patterns each protruding out to the left and right, but is not limited to this. When m and n are both integers greater than or equal to four (here, m=n), it may be such that a reticle pattern has a plurality of chip patterns in which chip patterns in the four corners are taken away from a quadrangular shape of m×n chip patterns which are arranged so that the maximum number of chip patterns (arrangement with a greater number of chip patterns in comparison to the quadrangular shape arrangement of FIGS. 3(a) and (b)) are inscribed in or chip patterns are not jutting out from a circle of an effective exposure region, or in another point of view, when m and n are both integers greater than or equal to two, it may be such that the reticle pattern has an even number of chip patterns protruding out from all four sides of an m×n quadrangular chip pattern to the top and bottom or/and left and right which are arranged so that the maximum number of chip patterns are inscribed in or chip patterns are not jutting out from a circle of an effective exposure region.

In other words, a reticle pattern may be such that a plurality of chip patterns are arranged in a line-symmetrical configuration to the top and bottom and left and right in a plane view along a scribe line between chip patterns, such that a maximum number of chip patterns are arranged to be inscribed in or without jutting out from a circle of effective exposure region.

### Embodiment 2

In the above-described Embodiment 1, the reticle mounted with twelve chip patterns in the effective exposure region 23 has been described. However, in Embodiment 2, a reticle mounted with twenty four chip patterns in an effective exposure region will be described.

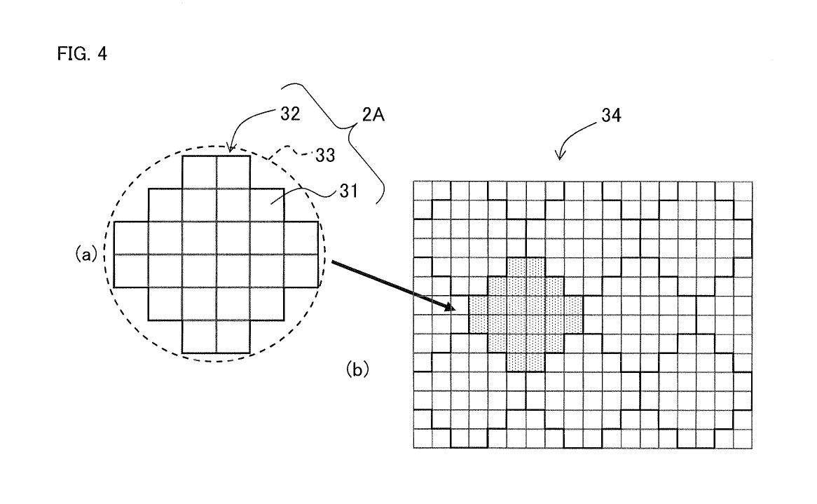

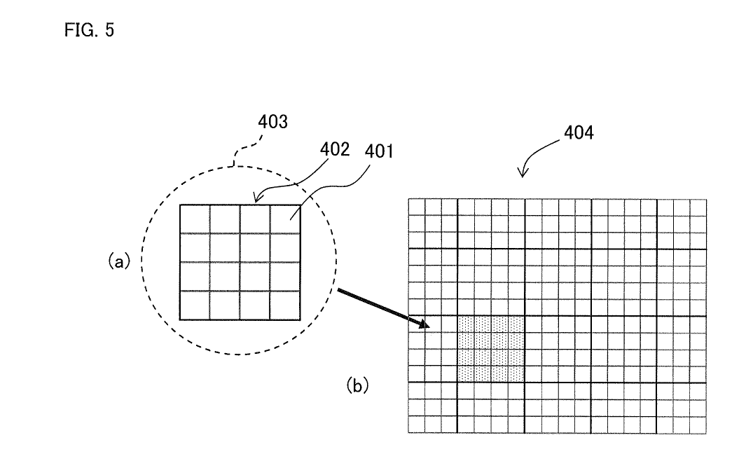

FIG. 4 is an explanatory diagram of Embodiment 2 of an exposure method using a reticle for exposure 2A of FIG. 1. FIG. 4(a) is a plane view illustrating the relationship between a reticle pattern and an effective exposure region. FIG. 4(b) is a diagram of sequential exposure patterns to a wafer 4. FIG. 5 is an explanatory diagram of an exposure method using the conventional reticle for exposure as a comparative example of FIG. 4. FIG. 5(a) is a plane view illustrating the relationship between a reticle pattern and an effective exposure region. FIG. 5(b) is a diagram of sequential exposure patterns to a wafer.

In FIGS. 5(a) and 5(b), in the conventional exposure method, reduced projection exposure is performed sequentially on a surface of a wafer 404, on which a photo resist film (photosensitive resist film) is formed, using a reticle for exposure formed such that a reticle pattern 402 with a square outer shape having, for example, 4×4 or sixteen chip patterns 401 is inscribed in a circle of an effective exposure region 403, which is a high resolution region. In the conventional reticle for exposure, since the square reticle pattern 402 is used, a chip pattern 401 cannot be accommodated any more even if the area of the effective exposure region 403 has more space.

In contrast, in FIGS. 4(a) and 4(b), in an exposure method using a reticle for exposure 2A of Embodiment 2, reduced projection exposure is performed sequentially on a surface of a wafer 34, on which a photoresist film is formed, using the reticle for exposure 2A formed such that a reticle pattern 32 that is line-symmetrical to the top and bottom and left and right having, for example, twenty four chip patterns 31 resulting from taking away three chip patterns each from the four corners and the corner sections adjacent thereto of 6×6 or thirty six chip patterns 31 is inscribed in a circle of an effective exposure region 33, which is a high resolution region. For the line symmetry to the top and bottom and left and right, a line of line-symmetry is positioned along a scribe line between chip patterns 31. In the reticle pattern 32, chip patterns 31 protrude out from each of the center section (two chip patterns 31) of four sides of the reticle pattern constituted of 4×4 or sixteen chip patterns 31, with two chip patterns each protruding out to the top and bottom, and also two chip patterns each protruding out to the left and right. In this case, if the reticle pattern 32 of this shape is sequentially exposed on the wafer 34, on which a photoresist film is formed, the reticle pattern 32 is arranged as in FIG. 4(b), with the consecutive reticle patterns 32 in the first row and the second row being offset by half a pitch. Specifically, when the reticle patterns 32 that protrude out to the top and bottom for the amount of two chip patterns 31 are sequentially exposed, the reticle patterns 32 form a shape with depressions for the amount of two chip patterns 31 on the top and bottom of the left and right boundary position between the reticle patterns 32. A reticle pattern 32 protruding out for the amount of two chip patterns 31 fits in perfectly with the shape of the depression for the amount of two chip patterns 31. In this manner, in order for the reticle patterns 32 to fit in perfectly in the first row and the second row, the number of chip patterns 31 that protrude out needs to be an even number.

In an exposure process for exposing and patterning the photoresist film on the wafer 34 in a predetermined shape, the photoresist film is exposed by using the reticle pattern 32 with a stair-like shape of a shot instead of a square or a rectangle illustrated in FIGS. 5(a) and 5(b) such that the outer shape is inscribed in or does not jut out from the circle of the effective exposure region 33. As in the arrangement of twenty four chip patterns 31 on the reticle for exposure 2A, chip patterns 31 are arranged, such that more chip patterns 31 are in the circular effective exposure region 33 that is a high resolution region. Although the chip size is the same as in the above-described conventional exposure method, the number of chip patterns is increased from sixteen chip patterns to twenty four chip patterns in one shot for exposure. It is not required that the shape of a shot of the reticle pattern 32 is made to be a square or a rectangle in a plane view at this time. At the time of exposure on the wafer 34, a plurality of chip patterns 31 are devised to be arranged in the effective exposure region 33 on the reticle for exposure 2A, such that more chip patterns can be arranged without space between each patterns at the time of sequential exposure.

In order to arrange more chip patterns in the effective exposure region 33 on the reticle for exposure 2A, the shapes of shots of adjacent reticle patterns 32 are arranged efficiently on the wafer 34 to be repeatedly arranged without space and in a line in the horizontal or vertical directions, by arranging chip patterns 31 in a stair-like outer shape such that more chip patterns 31 are inscribed to the maximum degree in a writing region (effective exposure region 33) and by devising a shot arrangement on the wafer 34.

The reticle pattern 32 is a pattern arranged in a stair-like outer shape so that more chip patterns 31 are inscribed to the maximum degree in a writing region (effective exposure region 33). The reticle pattern 32 is repeatedly arranged with no space between shots and in a line in the horizontal and vertical directions.

From the above, according to Embodiment 2, the reticle pattern 32 has twenty four chip patterns 31 wherein three chip patterns each in the four corners and the corner sections adjacent thereto are taken out from 6×6 36 chip patterns, or in another point of view, in the reticle pattern 32, chip patterns 31 protrude out from each of the center section (two chip patterns 31) of four sides of the reticle pattern constituted of 4×4 or sixteen chip patterns 31, with two chip patterns 31 each protruding out to the top and bottom, and also two chip patterns 31 each protruding out to the left and right.

Thereby, in the conventional exposure method illustrated in FIGS. 5(a) and 5(b), exposure of the reticle pattern 402 constituted of sixteen chip patterns 401 per shot is possible. However, in the exposure method using the reticle for exposure 2A of Embodiment 2 illustrated in FIGS. 4(a) and 4(b), exposure of the reticle pattern 32 constituted of twenty four chip patterns 31 per shot is possible. Thereby, in the exposure method of Embodiment 2, throughput is improved 24/16 times in comparison to the conventional exposure method. In this manner, utilizing the effective exposure region 33 in a most effective manner and improving throughput are made possible by increasing the number of chip patterns per shot and fitting in reticle patterns 32 with each other with no space without complicating the step feeding.

In Embodiment 2, as in FIG. 4, a case is described where the reticle pattern 32 has twenty four chip patterns 31 wherein each of the three chip patterns in the four corners and the corner sections adjacent thereof are taken out from the 6×6 or 36 chip patterns 31, or in another point of view, a case is described where chip patterns 31 protrude out from each of the center section (two chip patterns 31) of four sides of the reticle pattern constituted of 4×4 or sixteen chip patterns 31, with two chip patterns 31 each protruding out to the top and bottom and also two chip patterns 31 each protruding out to the left and right, but is not limited to this. When m and n are both integers greater than or equal to six (here, m=n), it may be such that a reticle pattern has a plurality of chip patterns in which chip patterns in the four corners and one or more adjacent to the chip patterns in the four corners are taken away from a plurality of chip patterns with an m×n quadrangular shape which are arranged so that the maximum number of chip patterns (arrangement with a greater number of chip patterns in comparison to the quadrangular shape arrangement of FIGS. 5(a) and 5(b)) are inscribed in or chip patterns are not jutting out from a circle of an effective exposure region, or in another point of view, when m and n are both integers greater than or equal to four, it may be such that the reticle pattern has an even number of chip patterns protruding out from all four sides of an m×n quadrangular chip patterns to the top and bottom or/and left and right which are arranged so that the maximum number of chip patterns are inscribed in or chip patterns are not jutting out from a circle of an effective exposure region. In this case, the reticle patter is configured with a stair-like outer shape, such that the reticle pattern is inscribed in or does not jut out from the circle of the effective exposure region.

In other words, the reticle pattern may be such that a plurality of chip patterns are arranged in a line-symmetrical configuration to the top and bottom and left and right in a plane view along a scribe line between chip patterns, such that a maximum number of chip patterns are arranged to be inscribed in or without jutting out from a circle of an effective exposure region.

### Embodiment 3

In the above-described Embodiment 1, a reticle mounted with twelve chip patterns in the effective exposure region 23 has been described. In Embodiment 2, a reticle mounted with twenty four chip patterns in the effective exposure region 33 has been described. However, in Embodiment 3, a reticle mounted with forty chip patterns in an effective exposure region will be described.

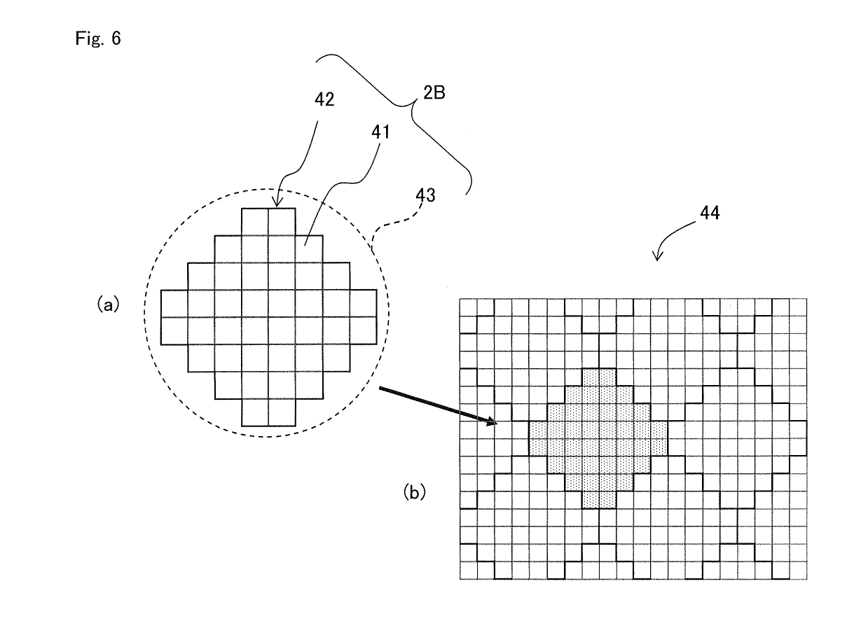

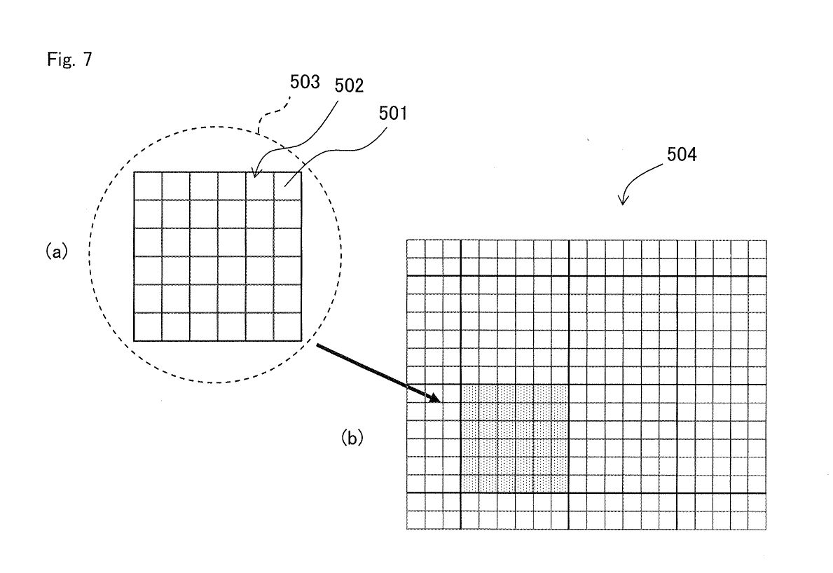

FIG. 6 is an explanatory diagram of Embodiment 3 of an exposure method using a reticle for exposure 2B of FIG. 1. FIG. 6(a) is a plane view illustrating the relationship between a reticle pattern and an effective exposure region. FIG. 6(b) is a diagram of sequential exposure patterns to a wafer 4. FIG. 7 is an explanatory diagram of an exposure method using the conventional reticle for exposure as a comparative example of FIG. 6. FIG. 7(a) is a plane view illustrating the relationship between a reticle pattern and an effective exposure region. FIG. 7(b) is a diagram of sequential exposure patterns to a wafer.

In FIGS. 7(a) and 7(b), in the conventional exposure method, reduced projection exposure is performed sequentially on a surface of a wafer 504, on which a photo resist film (photosensitive resist film) is formed, using a reticle for exposure formed such that a reticle pattern 502 with a square outer shape having, for example, 6×6 or thirty six chip patterns 501 is inscribed in a circle of an effective exposure region 503, which is a high resolution region. In the conventional reticle for exposure, since the square reticle pattern 502 is used, a chip pattern 501 cannot be accommodated any more even if the area of the effective exposure region 503 has more space.

In contrast, in FIGS. 6(a) and 6(b), in an exposure method using a reticle for exposure 2B of Embodiment 3, reduced projection exposure is performed sequentially on a surface of a wafer 44, on which a photoresist film is formed, using the reticle for exposure 2B formed such that a reticle pattern 42 that is line-symmetrical to the top and bottom and left and right having, for example, forty chip patterns 41 resulting from taking away six chip patterns each from the four corner sections of 8×8 or sixty four chip patterns 41 is inscribed in a circle of an effective exposure region 43, which is a high resolution region. For the line symmetry to the top and bottom and left and right, a line of line-symmetry is positioned along a scribe line between chip patterns 41. In the reticle pattern 42, each chip pattern 41 of four corners are taken away from a reticle pattern constituted of 6×6 or thirty six chip patterns 41 and chip patterns 41 protrude out from each of the center section (two chip patterns 41) of four sides of the reticle pattern constituted of 6×6 or thirty six chip patterns 41, with two chip patterns 41 each that protrude out to the top and bottom, and also two chip patterns 41 each in the center sections protruding out to the left and right. In this case, if the reticle pattern 42 of this shape is sequentially exposed on the wafer 44, on which a photoresist film is formed, the reticle pattern 42 is arranged sequentially as in FIG. 6(b), with the consecutive reticle patterns 42 in the first row and the second row being offset by half a pitch. Specifically, when the reticle patterns 42 that protrude out to the top and bottom for the amount of two chip patterns 41 are sequentially exposed, the reticle patterns 42 form a shape with depressions for the amount of two chip patterns 41 on the top and bottom of the left and right boundary position between the reticle patterns 42. A reticle pattern 42 protruding out for the amount of two chip patterns 41 is fitting in perfectly with the shape of the depression for the amount of two chip patterns 41. In this manner, in order for the reticle patterns 42 to fit in perfectly in the first row and the second row, the number of chip patterns 41 that protrude out needs to be an even number.

In an exposure process for exposing and patterning the photoresist film on the wafer 44 in a predetermined shape, the photoresist film is exposed by using the reticle pattern 42 with a stair-like shape of a shot instead of a square or a rectangular shape illustrated in FIGS. 7(a) and 7(b) such that the outer shape is inscribed in or does not jut out from the circle of the effective exposure region 43. As in the arrangement of forty chip patterns 41 on the reticle for exposure 2B, chip patterns 41 are arranged, such that the most number of chip patterns 41 are in the circular effective exposure region 43 that is a high resolution region. Although the chip size is the same as in the above-described conventional exposure method, the number of chip patterns is increased from thirty six chip patterns to forty chip patterns in one shot for exposure. It is not required that the shape of a shot of the reticle pattern 42 is made to be a square or a rectangle in a plane view at this time. At the time of exposure on the wafer 44, a plurality of chip patterns 41 are devised to be arranged in the effective exposure region 43 on the reticle for exposure 2B, such that the most number of chip patterns can be arranged without space between each patterns at the time of sequential exposure.

In order to arrange the most number of chip patterns in the effective exposure region 43 on the reticle for exposure 2B, the shapes of shots of adjacent reticle patterns 42 are arranged efficiently on the wafer 44 to be repeatedly arranged without space and in a line in the horizontal or vertical directions, by arranging chip patterns 41 in a stair-like outer shape such that the most number of chip patterns 41 are inscribed to the maximum degree in a writing region (effective exposure region 43) and by devising a shot arrangement on the wafer 44.

The reticle pattern 42 is a pattern arranged in a stair-like outer shape so that the most number of chip patterns 41 are inscribed to the maximum degree in a writing region (effective exposure region 43). The reticle pattern 42 is repeatedly arranged with no space between shots and in a line in the horizontal and vertical directions.

From the above, according to Embodiment 3, the reticle pattern 42 has forty chip patterns 41 wherein six chip patterns each of four corner sections, in four corners and one or a plurality of consecutive chip patterns adjacent the four corners inside and on the outer circumference, are taken out from 8×8 or sixty four chip patterns, or in another point of view, in the reticle pattern 42, each chip pattern 41 in the four corners are taken out from the reticle pattern constituted of 6×6 or thirty six chip patterns 41 and chip patterns 41 protrude out from each of the center section (two chip patterns 41) of four sides of the reticle pattern constituted of 6×6 or thirty six chip patterns 41, with two chip patterns 41 each protruding out to the top and bottom, and also two chip patterns 41 each protruding out to the left and right.

Thereby, in the conventional exposure method illustrated in FIGS. 7(a) and 7(b), exposure of the reticle pattern 502 constituted of thirty six chip patterns 501 per shot is possible. However, in the exposure method using the reticle for exposure 2B of Embodiment 3 illustrated in FIGS. 6(a) and 6(b), exposure of the reticle pattern 42 constituted of forty chip patterns 41 per shot is possible. Thereby, in the exposure method of Embodiment 3, throughput is improved 40/36 times in comparison to the conventional exposure method. In this manner, utilizing the effective exposure region 43 in a most effective manner and improving throughput are made possible by increasing the number of chip patterns per shot and fitting in reticle patterns 42 with each other with no space without complicating the step feeding.

In Embodiment 3, as in FIG. 6, a case is described where the reticle pattern 42 has forty chip patterns 41 wherein six chip patterns each of four corner sections, in four corners and one or a plurality of consecutive chip patterns adjacent the four corners inside and on the outer circumference, are taken out from 8×8 or sixty four chip patterns 41, or in another point of view, a case is described where each chip pattern 41 in the four corners are taken out from the reticle pattern constituted of 6×6 or thirty six chip patterns 41 and chip patterns 41 protrude out from each of the center section (two chip patterns 41) of four sides of the reticle pattern constituted of 6×6 or thirty six chip patterns 41, with two chip patterns 41 each protruding out to the top and bottom and also two chip patterns 41 each protruding out the center sections to the left and right, but is not limited to this. When m and n are both integers greater than or equal to eight (here, m=n), it may be such that a reticle pattern has a plurality of chip patterns where a plurality of chip patterns each (for example, six chip patterns each) of four corner sections, in four corners and one or a plurality of consecutive chip patterns adjacent the four corners inside and on the outer circumference, are taken away from a plurality of chip patterns with an m×n quadrangular shape which are arranged so that the maximum number of chip patterns (arrangement with a greater number of chip patterns in comparison to the quadrangular shape arrangement of FIGS. 7(a) and 7(b)) are inscribed in or chip patterns are not jutting out from the circle of the effective exposure region 43, or in another point of view, when m and n are both integers greater than or equal to six, it may be such that the reticle pattern has each of the chip patterns 41 in the four corners of an m×n quadrangular chip patterns taken away and has an even number of chip patterns protruding out from the center sections of four sides of an m×n quadrangular chip patterns to the top and bottom or/and left and right which are arranged so that the maximum number of chip patterns are inscribed in or chip patterns are not jutting out from a circle of an effective exposure region. In this case, the reticle pattern is configured in a stair-like outer shape such that the reticle pattern is inscribed in or does not jut out from the circle of the effective exposure region.

In other words, a reticle pattern may be such that a plurality of chip patterns are arranged in a line-symmetrical configuration to the top and bottom and left and right in a plane view along a scribe line between chip patterns, such that a maximum number of chip patterns are arranged to be inscribed in or without jutting out from a circle of an effective exposure region.

In the above-described Embodiment 3, the reticle pattern 42 having forty chip patterns 41 such that the maximum number of chip patterns are arranged to be inscribed in or without jutting out from the circle of the effective exposure region 43 has been described. However, an LED element is small and several hundred to several thousand chip patterns of LED elements can be in the circle of the effective exposure region 43. Thus, a reticle pattern has a far greater number of chip patterns than in the case of the above-described Embodiment 3.

### Embodiment 4

In the above-described Embodiments 1 to 3, cases have been described where a reticle pattern has a plurality of chip patterns arranged line-symmetrically top and bottom and left and right in a plane view with respect to a line along a scribe line between chip patterns as a mid line.

However, in Embodiment 4, a case will be described where a reticle pattern has a plurality of chip patterns arranged line-symmetrically top and bottom or left and right in a plane view with respect to a line along a scribe line between chip patterns as a mid line. In other words, in Embodiments 1 to 3, a case of both the top and bottom sides and the left and right sides having even number of chip patterns have been described, but in Embodiment 4, a case of either the top and bottom sides or the left and right sides having even number of chip patterns will be described. Specifically, the number of chip patterns on the top and bottom sides is two, and the number of chip patterns on the left and right sides is three.

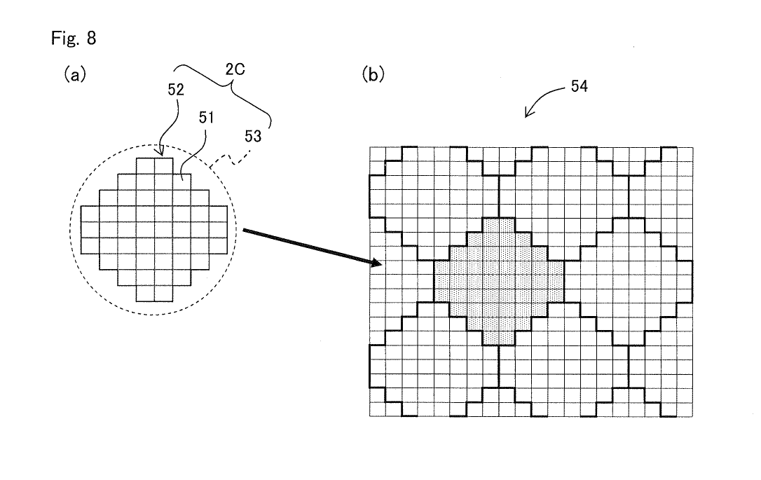

FIG. 8 is an explanatory diagram of Embodiment 4 of an exposure method using a reticle for exposure 2C of FIG. 1. FIG. 8(a) is a plane view illustrating the relationship between a reticle pattern and an effective exposure region. FIG. 8(b) is a diagram of sequential exposure patterns to a wafer 4.

In FIGS. 8(a) and 8(b), in the exposure method using a reticle for exposure 2C of Embodiment 4, reduced projection exposure is performed sequentially on a surface of a wafer 54, on which a photo resist film is formed, using a reticle for exposure 2C formed such that a reticle pattern 52 that is line-symmetrical to the top and bottom or left and right along a scribe line between chip patterns having, for example, forty eight chip patterns 51 resulting from taking away each of the six chip patterns of the four corner sections from 8×9 or seventy two chip patterns 51 is inscribed in or does not jut out from a circle of an effective exposure region 53, which is a high resolution region. In this case, the number of chip patterns on the top and bottom sides of forty eight chip patterns 51 is two, which is an even number, and the number of chip patterns on the left and right sides is three, which is an odd number. When sequentially exposed, forty eight chip patterns 51 are arranged such that the top part of another reticle pattern 52 fits into, with a half pitch offset, the bottom position of reticle patterns 52 adjacent to each other to the left and right without space.

For this line symmetry to the left and right, the line of line-symmetry is positioned along a scribe line between the left four columns of chip patterns 51 and the right four columns of chip patterns 51. On the other hand, for the line symmetry to the top and bottom, since there is a row of nine chip patterns 51 between the top four rows of chip patterns 51 and the bottom four rows of chip patterns 51, the line of line-symmetry is not along a scribe line. The line of line-symmetry is the longitudinal direction mid line of a row of eight chip patterns 51 in the middle of column direction. Accordingly, the reticle pattern 52 is not line-symmetrical to the top and bottom and left and right in a plane view along a scribe line between chip patterns 51 as in the case of the above-described Embodiment 1, and forty eight chip patterns 51 are arranged line-symmetrically top and bottom or left and right in a plane view along a scribe line between chip patterns 51.

In the reticle pattern 52, each chip pattern 51 in the four corners are taken out from the reticle pattern constituted of 6×7 or forty two chip patterns 51 and chip patterns 51 protrude out from each of the center section of four sides of the reticle pattern constituted of 6×7 or forty two chip patterns 51, with two chip patterns 51 each protruding out to the top and bottom, which is an even number, and three chip patterns 51 each protruding out to the left and right, which is an odd number. In this case, when the reticle pattern 52 of this shape is sequentially exposed on the wafer 54, on which a photoresist film is formed, the reticle patterns 52 are exposed for sequentially arrangement in the row and column directions as in FIG. 8(b) with consecutive reticle patterns 52 on the first row and the second row being offset by a half pitch. Specifically, when the reticle patterns 52 that protrude out to the top and bottom for the amount of two chip patterns 51 are sequentially exposed to the left and right, the reticle patterns 52 form a shape with depressions for the amount of two chip patterns 51 on the top and bottom of the left and right boundary positions between the reticle patterns 52 that are adjacent to the left and right. A reticle pattern 52 protruding out for the amount of two chip patterns 51 is fitting in perfectly with the shape of the depression for the amount of two chip patterns 51 without space. In this manner, in order for the reticle patterns 52 to fit in perfectly in the first row and the second row without space, the number of chip patters 51 that protrude out needs to be an even number.

In an exposure process for exposing and patterning the photoresist film on the wafer 54 in a predetermined shape, the photoresist film is exposed by using the reticle pattern 52 with a stair-like shape of a shot such that the outer shape is inscribed in or does not jut out from the circle of the effective exposure region 53. As in the arrangement of forty eight chip patterns 51 on the reticle for exposure 2C, chip patterns 51 are arranged, such that the most number of chip patterns 51 are in the circular effective exposure region 53 that is a high resolution region. Although the chip size is the same as in the above-described conventional exposure method, the number of chip patterns is increased from 6×7 or forty two chip patterns to forty eight chip patterns in one shot for exposure. It is not required that the shape of a shot of the reticle pattern 52 is made to be a square or a rectangle in a plane view at this time. At the time of exposure on the wafer 54, a plurality of chip patterns 51 are devised to be arranged in the effective exposure region 53 on the reticle for exposure 2C, such that the most number of chip patterns can be arranged without space between each patterns at the time of sequential exposure.

In order to arrange the most number of chip patterns in the effective exposure region 53 on the reticle for exposure 2C, the shapes of shots of adjacent reticle patterns 52 are arranged efficiently on the wafer 54 to be repeatedly arranged without space and in a line in the horizontal or vertical directions, by arranging chip patterns 51 in a stair-like outer shape such that the most number of chip patterns 51 are inscribed to the maximum degree in or chip patterns do not jut out from a writing region (effective exposure region 53) and by devising a shot arrangement on the wafer 54.

The reticle pattern 52 is a pattern arranged in a stair-like outer shape so that the most number of chip patterns 51 are inscribed to the maximum degree in or chip patterns do not jut out from a writing region (effective exposure region 53). The reticle pattern 52 is repeatedly arranged with no space between shots and in a line in the horizontal and vertical directions.

From the above, according to Embodiment 4, the reticle pattern 52 has forty eight chip patterns 51 wherein six chip patterns each of four corner sections, in four corners and one or a plurality of consecutive chip patterns adjacent the four corners inside and on the outer circumference, are taken out from 8×9 seventy two chip patterns, or in another point of view, each chip pattern 51 in the four corners are taken out from the reticle pattern constituted of 6×7 or forty two chip patterns 51 and chip patterns 51 protrude out from each of the center section of four sides of the reticle pattern constituted of 6×7 or forty two chip patterns 51, with two chip patterns 51 each protruding out to the top and bottom and also three chip patterns 51 each protruding out to the left and right.

Thereby, in the conventional exposure method, exposure of the rectangular reticle pattern in a plane view constituted of 6×7 or forty two chip patterns per shot is possible. However, in the exposure method using the reticle for exposure 2C of Embodiment 4 illustrated in FIGS. 8(a) and 8(b), exposure of the reticle pattern 52 constituted of forty eight chip patterns 51 per shot is possible. Thereby, in the exposure method of Embodiment 4, throughput is improved 48/42 times in comparison to the conventional exposure method. In this manner, utilizing the effective exposure region 53 in a most effective manner and improving throughput are made possible by increasing the number of chip patterns per shot and fitting in reticle patterns 52 with each other with no space without complicating the step feeding.

In Embodiment 4, as in FIG. 8, a case is described where the reticle pattern 52 has forty eight chip patterns 51 wherein six chip patterns each of four corner sections, in four corners and one or a plurality of consecutive chip patterns adjacent the four corners inside and on the outer circumference, are taken out from 8×9 or seventy two chip patterns 51, or in another point of view, a case is described where each chip pattern 51 in the four corners is taken out from the reticle pattern constituted of 6×7 or forty two chip patterns 51 and chip patterns 51 protrude out from each of the center section of four sides of the reticle pattern constituted of 6×7 or forty two chip patterns 51, with two chip patterns 51 each protruding out to the top and bottom and three chip patterns 51 each at the center section protruding out to the left and right, but is not limited to this. When m is an integer greater than or equal to eight and n is greater than or equal to nine, it may be such that a reticle pattern has a plurality of chip patterns where a plurality of chip patterns each (for example, six chip patterns each) of four corner sections, in four corners and one or a plurality of consecutive chip patterns adjacent the four corners inside and on the outer circumference, are taken away from a plurality of chip patterns with an m×n quadrangular shape which are arranged so that the maximum number of chip patterns are inscribed in or chip patterns do not jut out from the circle of the effective exposure region 53 (arrangement with a greater number of chip patterns in comparison to the quadrangular shape arrangement of 6×7 or forty two), or in another point of view, when m is an integer greater than or equal to six and n is an integer greater than or equal to seven, it may be such that the reticle pattern has each of the chip patterns 51 in the four corners of a m×n quadrangular chip patterns taken away and has an even number of chip patterns protruding out from the center sections of all four sides of an m×n quadrangular chip patterns to the top and bottom or left and right which is arranged so that the maximum number of chip patterns are inscribed in or chip patterns do not jut out from the circle of the effective exposure region 53. In this case, the reticle pattern 52 is configured in a sequential stair-like outer shape such that the reticle pattern is inscribed in or does not jut out from the circle of the effective exposure region.

In other words, a reticle pattern 52 may be such that a plurality of chip patterns are arranged in a line-symmetrical configuration to the top and bottom or left and right in a plane view along a scribe line between chip patterns, such that a maximum number of chip patterns are arranged to be inscribed in or without jutting out from the circle of the effective exposure region 53.

In the above-described Embodiment 4, the reticle pattern 52 having forty eight chip patterns 51 such that the maximum number of chip patterns are arranged to be inscribed in or without jutting out from the circle of the effective exposure region 53 has been described. However, an LED element is small and elongated, and numerous chip patterns of LED elements can be in the circle of the effective exposure region 53. Thus, a reticle pattern has a far greater number of chip patterns than in the case of the above-described Embodiment 4. This will be described as the next Embodiment 5.

### Embodiment 5

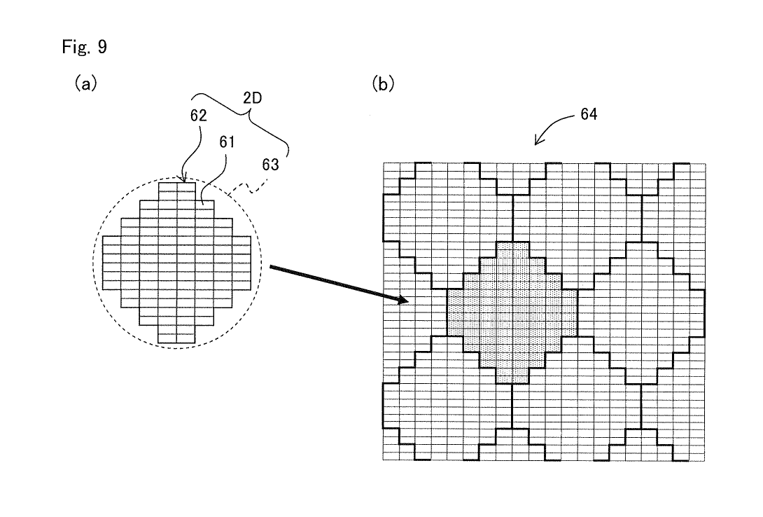

In the above-described Embodiment 4, a case has been described where a plurality of chip patterns are arranged line-symmetrically top and bottom or left and right in a plane view with respect to a scribe line between chip patterns 51 as the mid line in the reticle pattern 52, and the length and width of a chip pattern itself is equal. However, in Embodiment 5, in addition to the case where a plurality of chip patterns are arranged line-symmetrically top and bottom or/and left and right in a plane view with respect to a scribe line between chip patterns as the mid line in a reticle pattern, a case will be described where the length and width of a shape of a chip pattern in a plane view are different. In other words, in Embodiment 5, a case will be described where only one of the top and bottom sides and left and right sides of a reticle pattern needs to have even number of chip patterns, while, of course, both the top and bottom sides and the left and right sides can have even number of chip patterns, and the length and width of the chip patterns are different. Since an LED element has an elongated shape, an LED element corresponds to this. Specifically, a case will now be described using FIG. 9 where the number of chip patterns of the top and bottom sides is two, which is even, and the number of chip patterns of the left and right sides is six, which is also even.

FIG. 9 is an explanatory diagram of Embodiment 5 of an exposure method using a reticle for exposure 2D of FIG. 1. FIG. 9(a) is a plane view illustrating the relationship between a reticle pattern and an effective exposure region. FIG. 9(b) is a diagram of sequential exposure patterns to a wafer 4.

In FIGS. 9(a) and 9(b), in the exposure method using a reticle for exposure 2D of Embodiment 5, reduced projection exposure is performed sequentially in the directions of length and width on a surface of a wafer 64, on which a photo resist film is formed, using a reticle for exposure 2D formed such that a reticle pattern 62 that is line-symmetrical to the top and bottom or left and right along a scribe line (mid line) between chip patterns having, for example, ninety six chip patterns 61 resulting from taking away each of the twelve chip patterns of the four corner sections from 8×18 or one hundred forty four chip patterns 61 is inscribed in or does not jut out from a circle of an effective exposure region 63, which is a high resolution region. In this case, the number of chip patterns on the top and bottom sides of this ninety six chip patterns 61 is two each in the longitudinal direction, which is an even number, and the number on the left and right sides is six each in the short end direction, which is an even number. When sequentially exposed, ninety six chip patterns 61 are arranged without space such that the top part of another reticle pattern 62 fits into, with a half pitch offset, the bottom position of reticle patterns 62 adjacent to each other to the left and right (width direction) without space.

For this line symmetry to the left and right, the line of line-symmetry is positioned along a scribe line between the left four columns of chip patterns 61 and the right four columns of chip patterns 61. On the other hand, for the line symmetry to the top and bottom, the line of line-symmetry is line-symmetrical along a scribe line between the top nine rows of chip pattern 61 and the bottom nine rows of chip pattern 61. Accordingly, similarly to the case of the above-described Embodiment 1, ninety six chip patterns 61 are arranged line-symmetrically to both top and bottom and left and right in a plane view along a scribe line between chip patterns 61 as a mid line in the reticle pattern 62.

In the reticle pattern 62, two chip patterns 61 in each column direction in the four corners are taken out from the reticle pattern constituted of 6×14 or eighty four chip patterns 61 and chip patterns 61 protrude out from each of the center section of four sides of the reticle pattern constituted of 6×14 or eighty four chip patterns 61, with two chip patterns with a width of two for a total of four chip patterns 61 each protruding out to the top and bottom, which is an even number, and six chip patterns 61 each protruding out to the left and right, which is an even number. In this case, when the reticle pattern 62 of this shape is sequentially exposed on the wafer 64, on which a photoresist film is formed, the reticle patterns 62 are sequentially arranged in the column and row directions (length and width directions) as in FIG. 9(b) with consecutive reticle patterns 62 on the first row and the second row, or specifically the upper row and a row right below the upper row, being offset by a half pitch. When the reticle patterns 62 that protrude out to the top and bottom for the amount of the above-described two chip patterns with a width of two for a total of four chip patterns 61 are sequentially exposed to the left and right, the reticle patterns 62 form a shape with depressions for the amount of the above-described two chip patterns with a width of two for a total of four chip patterns 61 on the top and bottom of the left and right boundary positions between the reticle patterns 62 that are adjacent to the left and right. A reticle pattern 62 protruding out for the amount of two chip patterns with a width of two for a total of four chip patterns 61 is fitting in perfectly with the shape of the depression for the amount of two chip patterns with a width of two for a total of four chip patterns 61. In this manner, in order for the reticle patterns 62 to fit in perfectly in the first row and the second row without space, the width of chip patterns 61 that protrude out needs to be an even number.

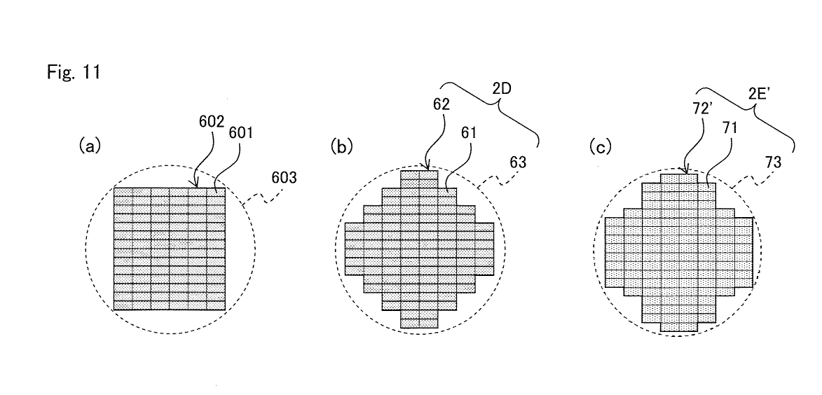

In an exposure process for exposing and patterning the photoresist film on the wafer 64 in a predetermined shape, the photoresist film is exposed by using the reticle pattern 62 with a uniform stair-like shape of a shot such that the outer shape is inscribed in or does not jut out from the circle of the effective exposure region 63. As in the arrangement of ninety six chip patterns 61 on the reticle for exposure 2D, chip patterns 61 are arranged, such that the most number of chip patterns 61 are in the circular effective exposure region 63 that is a high resolution region. Although the chip size is the same as in the above-described conventional exposure method, the number of chip patterns is increased from the conventional 6×14 or eighty four chip patterns to ninety six chip patterns of Embodiment 5 in one shot for exposure, as in FIG. 11(a) mentioned below. It is not required that the shape of the shot of the reticle pattern 62 is made to be a square or a rectangle in a plane view at this time. At the time of exposure on the wafer 64, a plurality of chip patterns 61 are devised to be arranged in the effective exposure region 63 on the reticle for exposure 2D, such that the most number of chip patterns can be fit in without space between each pattern at the time of sequential exposure.

In order to arrange the most number of chip patterns in the effective exposure region 63 on the reticle for exposure 2D, the shapes of shots of adjacent reticle patterns 62 are arranged efficiently on the wafer 64 to be repeatedly arranged without space and in a line in the horizontal or vertical directions, by arranging chip patterns 61 in a uniform stair-like outer shape such that the most number of chip patterns 61 are inscribed to the maximum degree in or chip patterns do not jut out from a writing region (effective exposure region 63) and by devising a shot arrangement on the wafer 64.

The reticle pattern 62 is a pattern arranged in a uniform stair-like outer shape so that the most number of chip patterns 61 are inscribed to the maximum degree in or chip patterns do not jut out from a writing region (effective exposure region 63). The reticle pattern 62 is repeatedly arranged with no space between shots and in a line in the horizontal and vertical directions.

From the above, according to Embodiment 5, the reticle pattern 62 has ninety six chip patterns 61 wherein twelve chip patterns each of four corner sections, in four corners and one or a plurality of consecutive chip patterns adjacent the four corners inside and on the outer circumference, are taken out from 8×18 one hundred forty four chip patterns, or in another point of view, two chip patterns 61 in each column direction (up and down direction) in the four corners are taken out from the reticle pattern constituted of 6×14 or eighty four chip patterns 61 and chip patterns 61 protrude out from each of the center section of four sides of the reticle pattern constituted of 6×14 or eighty four chip patterns 61, with four chip patterns 61 each protruding out to the top and bottom and six chip patterns 61 each protruding out from the center sections to the left and right.

Thereby, in the conventional exposure method, exposure of the rectangular reticle pattern in a plane view constituted of 6×14 or eighty four chip patterns 61 per shot is possible, as illustrated in FIG. 11(a) mentioned below. However, in the exposure method using the reticle for exposure 2D of Embodiment 5 illustrated in FIGS. 9(a) and 9(b), exposure of the reticle pattern 62 constituted of ninety six chip patterns 61 per shot is possible. Thereby, in the exposure method of Embodiment 5, throughput is improved 96/84 times in comparison to the conventional exposure method. In this manner, utilizing the effective exposure region 63 in a most effective manner and improving throughput are made possible by increasing the number of chip patterns per shot and fitting in reticle patterns 62 with each other with no space without complicating the step feeding.

In Embodiment 5, as in FIG. 9, a case is described where the reticle pattern 62 has ninety six chip patterns 61 wherein twelve chip patterns each of four corner sections, in four corners and one or a plurality of consecutive chip patterns adjacent the four corners inside and on the outer circumference, are taken out from 8×18 or one hundred forty four chip patterns 61, or in another point of view, a case is described where two chip patterns 61 in each column direction (up and down direction) in the four corners are taken out from the reticle pattern constituted of 6×14 or eighty four chip patterns 61 and chip patterns 61 protrude out from each of the center section of four sides of the reticle pattern constituted of 6×14 or eighty four chip patterns 61, with two chip patterns with a width of two for a total of four chip patterns 61 each protruding out to the top and bottom and six chip patterns 51 each for a total of twelve chips protruding out of the center sections to the left and right, but is not limited to this. When m is an integer greater than or equal to eight and n is an integer greater than or equal to eighteen, it may be such that a reticle pattern has a plurality of chip patterns where a plurality of chip patterns each (for example, twelve chip patterns each) of four corner sections, in four corners and one or a plurality of consecutive chip patterns adjacent the four corners inside and on the outer circumference, are taken away from a plurality of chip patterns with an m×n quadrangular shape which are arranged so that the maximum number of chip patterns are inscribed in or chip patterns do not jut out from the circle of the effective exposure region 63 (arrangement with a greater number of chip patterns in comparison to the quadrangular shape arrangement of 6×14 or eighty four), or in another point of view, when m is an integer greater than or equal to six and n is an integer greater than or equal to fourteen, it may be such that the reticle pattern has two chip patterns 61 in each column direction in the four corners of a m×n quadrangular chip patterns taken away and has an even number of chip patterns protruding out from the center sections of all four sides of an m×n quadrangular chip patterns to the top and bottom and/or left and right which are arranged so that the maximum number of chip patterns are inscribed in or chip patterns do not jut out from the circle of the effective exposure region 63. In this case, the reticle pattern 62 is configured in a uniform stair-like outer shape such that the reticle pattern is inscribed in or does not jut out from the circle of the effective exposure region.

In other words, a reticle pattern 62 may be such that a plurality of chip patterns 61 are arranged in a line-symmetrical configuration to the top and bottom and/or left and right in a plane view with respect to a mid line along a scribe line between chip patterns, such that a maximum number of chip patterns are arranged to be inscribed in or without jutting out from the circle of the effective exposure region 63.

### Embodiment 6

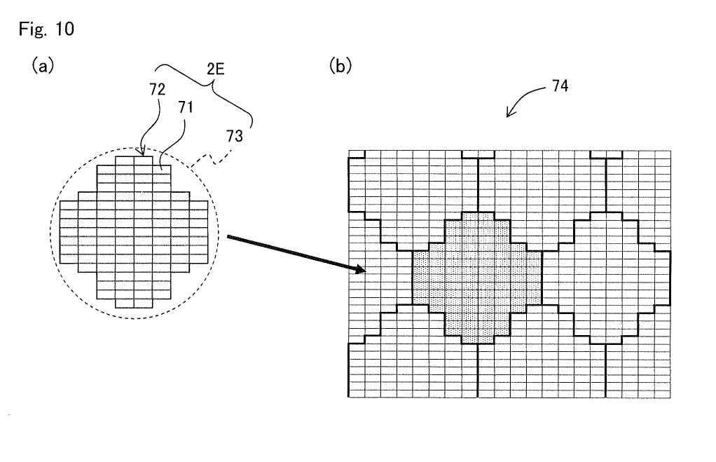

In the above-described Embodiments 1 to 5, cases have been described where a plurality of chip patterns are arranged in a stair-like shape of a shot with uniform intervals such that the outer shape of a reticle pattern is inscribed or does not jut out from the circle of the effective exposure region. However, in Embodiment 6, a case will be described where a plurality of chip patterns are arranged in a stair-like shape of a shot with uneven intervals such that the outer shape of a reticle pattern is inscribed in or does not jut out from a circle of an effective exposure region. In other words, Embodiment 6 is a case where a stair-like pitch is not a uniform interval. Also in this case, only either the top and bottom sides or left and right sides of a reticle pattern needs to be an even number, and a case will be described where the length and width of the shape of a chip pattern is different in a plane view. For example, since an LED element and the like has an elongated shape, an LED element corresponds to this. Specifically, a case will now be described using FIG. 10 where the number of chip patterns of the top and bottom sides is two, which is an even number, and the number of chip patterns of the left and right sides is seven, which is an odd number.

FIG. 10 is an explanatory diagram of Embodiment 6 of an exposure method using a reticle for exposure 2E of FIG. 1. FIG. 10(a) is a plane view illustrating the relationship between a reticle pattern and an effective exposure region. FIG. 10(b) is a diagram of sequential exposure patterns to a wafer 4.

In FIGS. 10(a) and 10(b), in the exposure method using a reticle for exposure 2E of Embodiment 6, reduced projection exposure is performed sequentially in the directions of length and width on a surface of a wafer 74, on which a photo resist film is formed, using a reticle for exposure 2E formed such that a reticle pattern 72 that is line-symmetrical to the top and bottom or left and right along a scribe line (mid line) between chip patterns having, for example, ninety six chip patterns 71 resulting from taking away each of the ten chip patterns of the four corner sections from 8×17 or one hundred thirty six chip patterns 71 is inscribed in or does not jut out from a circle of an effective exposure region 73, which is a high resolution region. In this case, the number of chip patterns on the top and bottom sides of this ninety six chip patterns 71 is two each in the longitudinal direction, which is an even number, and the number on the left and right sides is seven each in the short end direction, which is an odd number. When sequentially exposed, ninety six chip patterns 71 are arranged without space such that the top part of another reticle pattern 72 fits into, with a half pitch offset, the bottom position of reticle patterns 72 adjacent to each other to the left and right (width direction) without space.

For this line symmetry to the left and right, amid line of the line-symmetry is positioned along a scribe line between the left four columns of chip patterns 71 and the right four columns of chip patterns 71. On the other hand, for the line symmetry to the top and bottom, the reticle pattern is line-symmetrical with respect to a mid line of a row of eight chip patterns 71 in the row direction (width direction) between the top eight rows of chip patterns 71 and the bottom eight rows of chip patterns 71. Accordingly, similarly to the case of the above-described Embodiment 4, ninety six chip patterns 71 are arranged line-symmetrically top and bottom or left and right in a plane view along a scribe line between chip patterns 71 as a mid line in the reticle pattern 72.

In the reticle pattern 72, three chip patterns 71 in each column direction in the four corners are taken out from the reticle pattern constituted of 6×15 or ninety chip patterns 71 and chip patterns 71 protrude out from each of the center section of four sides of the reticle pattern constituted of 6×15 or ninety chip patterns 71, with two (width of two) chip patterns 71 each protruding out to the top and bottom, which is an even number, and seven chip patterns 71 each protruding out from the center sections to the left and right, which is an odd number. In this case, when the reticle pattern 72 of this shape is sequentially exposed on the wafer 74, on which a photoresist film is formed, the reticle patterns 72 are sequentially arranged in the column and row directions (length and width directions) as in FIG. 10(b) with consecutive reticle patterns 72 on the first row and the second row, or specifically the upper row and a row right below the upper row, being offset by a half pitch. When the reticle patterns 72 that protrude out to the top and bottom for the above-described amount of two chip patterns 71 each are sequentially exposed to the left and right, the reticle patterns 72 form a shape with depressions for the above-described amount of the two chip patterns 71 each on the top and bottom of the left and right boundary positions between the reticle patterns 72 that are adjacent to the left and right. A reticle pattern 72 protruding out for the amount of two chip patterns 61 each with a width of two chip patterns is fitting in perfectly with the shape of the depression for the amount of two chip patterns 71 each with a width of two chip patterns without space. In this manner, in order for the reticle patterns 72 to fit in perfectly in the first row and the second row without space, the width of chip patterns 71 that protrudes out needs to be an even number.

In an exposure process for exposing and patterning the photoresist film on the wafer 74 in a predetermined shape, the photoresist film is exposed by using the reticle pattern 72 with an uneven stair-like shape of a shot such that the outer shape is inscribed in or does not jut out from the circle of the effective exposure region 73. The pitch of a stair-like outer shape of the reticle pattern 72 is not at equal interval. Initially, the pitch goes down one step, and then goes down three steps, and finally goes down one step. As in the arrangement of ninety six chip patterns 71 on the reticle for exposure 2E, chip patterns 71 are arranged, such that the most number of chip patterns 71 are in the circular effective exposure region 73 that is a high resolution region. Although the chip size is the same as in the above-described conventional exposure method, the number of chip patterns is increased from the conventional 6×14 or eighty four chip patterns to ninety six chip patterns of Embodiment 6 in one shot for exposure, as in FIG. 11(a) mentioned below. It is not required that the shape of the shot of the reticle pattern 72 is made to be a square or a rectangle in a plane view at this time. At the time of exposure on the wafer 74, a plurality of chip patterns 71 are devised to be arranged in the effective exposure region 73 on the reticle for exposure 2E, such that the most number of chip patterns can be fit in without space between each patterns at the time of sequential exposure.

In order to arrange the most number of chip patterns in the effective exposure region 73 on the reticle for exposure 2E, the shapes of shots of adjacent reticle patterns 72 are arranged on the wafer 74 efficiently to be repeatedly arranged without space and in a line in the horizontal or vertical directions, by arranging chip patterns 71 in an uneven stair-like outer shape such that the most number of chip patterns 71 are inscribed to the maximum degree in or chip patterns do not jut out from a writing region (effective exposure region 73) and by devising a shot arrangement on the wafer 74.

The reticle pattern 72 is a pattern where the outer shape is arranged to have an uneven stair-like steps so that the most number of chip patterns 71 are inscribed to the maximum degree in or the chip patterns do not jut out from the writing region (effective exposure region 73). The reticle pattern 72 is repeatedly arranged with no space between shots and in a line in the horizontal and vertical directions.

From the above, according to Embodiment 6, the reticle pattern 72 has ninety six chip patterns 71 wherein ten chip patterns 71 each of four corner sections, in four corners and one or a plurality of consecutive chip patterns adjacent the four corners to inside (three in the column direction) and to the outer circumference, are taken out from 8×17 or one hundred thirty six chip patterns, or in another point of view, three chip patterns 71 in each column direction in the four corners are taken out from the reticle pattern constituted of 6×15 or ninety chip patterns 71 and chip patterns 71 protrude out from each of the center sections of four sides of the reticle pattern constituted of 6×15 or ninety chip patterns 71, with two chip patterns 71 each protruding out to the top and bottom and seven chip patterns 71 each protruding out from the center sections to the left and right.

Thereby, in the conventional exposure method, exposure of the rectangular reticle pattern in a plane view constituted of 6×14 or eighty four chip patterns 71 per shot is possible, as illustrated in FIG. 11(a) mentioned below. However, in the exposure method using the reticle for exposure 2E of Embodiment 6 illustrated in FIGS. 10(a) and 10(b), exposure of the reticle pattern 72 constituted of ninety six chip patterns 71 per shot is possible. Thereby, in the exposure method of Embodiment 6, throughput is improved 96/84 times in comparison to the conventional exposure method. In this manner, utilizing the effective exposure region 73 in a most effective manner and improving throughput are made possible by increasing the number of chip patterns per shot and fitting in reticle patterns 72 with each other with no space without complicating the step feeding.

In Embodiment 6, as in FIG. 10, a case is described where the reticle pattern 72 has ninety six chip patterns 71 wherein ten chip patterns each of four corner sections, in four corners and one or a plurality of consecutive chip patterns adjacent the four corners to inside (three chips to the column direction) and to the outer circumference, are taken out from 8×17 or one hundred thirty six chip patterns 71, or in another point of view, a case is described where three chip patterns 71 in each column direction in the four corners are taken out from the reticle pattern constituted of 6×15 or ninety chip patterns 71 and chip patterns 71 protrude out from each of the center section of four sides of the reticle pattern constituted of 6×15 or ninety chip patterns 71, with two chip patterns 71 each protruding out to the top and bottom and seven chip patterns 71 each protruding out from the center sections to the left and right, but is not limited to this. When m is an integer greater than or equal to eight and n is an integer greater than or equal to seventeen, it may be such that a reticle pattern has a plurality of chip patterns where each chip patterns of four corner sections, in four corners and one or a plurality of consecutive chip patterns adjacent the four corners inside and on the outer circumference (for example, ten chip patterns each), are taken away from a plurality of chip patterns with an m×n quadrangular shape which are arranged so that the maximum number of chip patterns are inscribed in or chip patterns do not jut out from the circle of the effective exposure region 73 (arrangement with a greater number of chip patterns in comparison to the quadrangular shape arrangement of 6×14 or eighty four), or in another point of view, when m is an integer greater than or equal to six and n is an integer greater than or equal to fifteen, it may be such that the reticle pattern has three chip patterns 71 in each column direction in the four corners of an m×n quadrangular chip patterns taken away and has an even number of chip patterns protruding out from the center sections of all four sides of an m×n quadrangular chip patterns to the top and bottom or left and right which are arranged so that the maximum number of chip patterns are inscribed in or chip patterns do not jut out from the circle of the effective exposure region 73. In this case, the outer shape of the reticle pattern 72 is configured to have uneven stair-like steps such that the reticle pattern is inscribed in or does not jut out from the circle of the effective exposure region.

In other words, a reticle pattern 72 may be such that a plurality of chip patterns 71 are arranged in a line-symmetrical configuration to the top and bottom or/and left and right in a plane view with respect to a mid line along a scribe line between chip patterns, such that a maximum number of chip patterns are arranged to be inscribed in or chip patterns do not jut out from the circle of the effective exposure region 73.

A comparison of the conventional exposure method to the above-described Embodiments 5 and 6 will be described with reference to FIGS. 11(a) to 11(c).

FIG. 11(a) is a plane view illustrating the relationship between a reticle pattern per shot by a conventional exposure method and an effective exposure region. FIG. 11(b) is a plane view illustrating the relationship between a reticle pattern of the above-described Embodiment 5 and an effective exposure region. FIG. 11(c) is a plane view illustrating the relationship between a modified example of a reticle pattern of the above-described Embodiment 6 and an effective exposure region. The effective exposure region 603 corresponds to each of the effective exposure region 63 and 73, which are regions having the same area as region 603.

In the conventional exposure method of FIG. 11(a), the outer shape of the reticle pattern is a square or a rectangle in a plane view, and exposure of a rectangular reticle pattern 602 in a plane view constituted of 6×14 or eighty four chip patterns 601 per shot is possible. In the exposure method using a reticle for exposure 2D of FIG. 9, as illustrated in the above-described Embodiment 5 of FIG. 11(b), exposure of the reticle pattern 62 constituted of ninety six chip patterns 61 per shot is possible. Thereby, in the exposure method of Embodiment 5, throughput is improved 96/84 times in comparison to the conventional exposure method.

Further, in the exposure method of the above-described Embodiment 6, exposure of the reticle pattern 72 constituted of ninety six chip patterns 71 per shot is possible. Thereby, in the exposure method of Embodiment 6, throughput is also improved 96/84 times in comparison to the conventional exposure method.

Moreover, in the exposure method using a modified example of the reticle for exposure 2E of FIG. 10 (reticle for exposure 2E′) of the above-described Embodiment 6 of FIG. 11(c), there is one more row of eight chip patterns 71 in comparison to the exposure method of the above-described Embodiment 6. Accordingly, exposure of a reticle pattern 72′ constituted of one hundred four chip patterns 71 per shot is possible. Thereby, in the exposure method of a modified example of Embodiment 6, throughput is improved 104/84 times in comparison to the conventional exposure method.

### Embodiment 7

In the above-described Embodiments 1 to 6, a case has been described where the reticle pattern is line-symmetrical along a scribe line between chip patterns as a mid line to the top and bottom and/or left and right. However, in Embodiment 7, a case will be described where the outer shape of a reticle pattern has no such line-symmetry and is asymmetrical. In other words, the reticle pattern may be such that the outer shape of the reticle pattern has more chip patterns in comparison to the number of chip patterns of a quadrangular outer shape in a plane view such that the reticle pattern is arranged to be inscribed in or does not jut out of a circle of an effective exposure region to the maximum degree and when sequentially exposed, a plurality of chip patterns are arranged such that the top part of a reticle pattern fits in with the bottom position of reticle patterns adjacent to each other to the left and right without space.

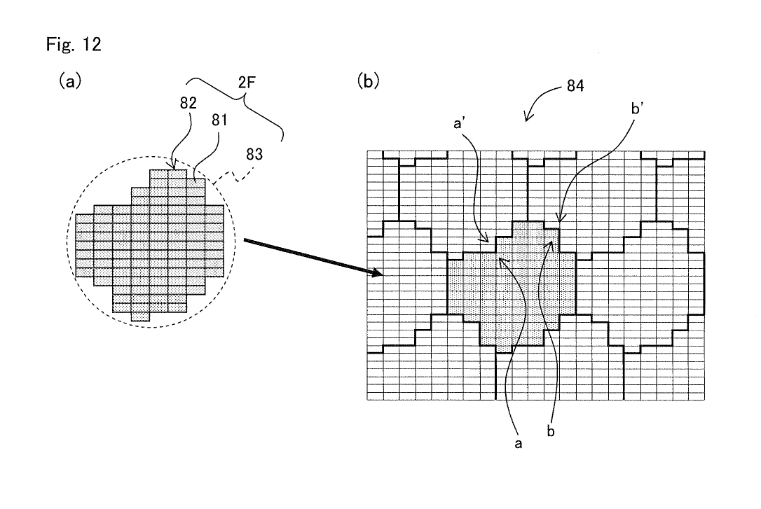

FIG. 12 is an explanatory diagram of Embodiment 7 of an exposure method using a reticle for exposure 2F of FIG. 1. FIG. 12(a) is a plane view illustrating the relationship between a reticle pattern and an effective exposure region. FIG. 12(b) is a diagram of sequential exposure patterns to a wafer 4.

In FIGS. 12(a) and 12(b), in an exposure method using a reticle for exposure 2F of Embodiment 7, reduced projection exposure is performed sequentially in the directions of length and width on a surface of a wafer 84, on which a photo resist film is formed, using a reticle for exposure 2F formed such that a reticle pattern 82 that is asymmetrical having no restrictions such as line symmetry and having ninety six chip patterns 81 is inscribed in or does not jut out from a circle of an effective exposure region 83, which is a high resolution region. In this case, ninety six chip patterns 81 are arranged so that the number of chip patterns is greater for the outer shape of the reticle pattern 82 arranged to be inscribed in or without jutting out from the circle of the effective exposure region 83 in comparison to the number of chip patterns of a quadrangular shape in a plane view. When sequentially exposed, ninety six chip patterns 81 are arranged such that the top part of the reticle pattern 82 fits into the bottom position of reticle patterns 82 adjacent to each other to the left and right without space.

In an exposure process for exposing and patterning the photoresist film on the wafer 84 in a predetermined shape, the photoresist film is exposed by using the reticle pattern 82 with an uneven stair-like shape of a shot such that the outer shape is inscribed in or does not jut out from the circle of the effective exposure region 83. The pitch of a stair-like outer shape of the reticle pattern 82 is not at equal interval. In the outer shape of the top left side, initially, the pitch goes down two steps, and then goes down two steps, and next the step does not go down, and finally goes down one step. As in the arrangement of ninety six chip patterns 81 on the reticle for exposure 2F, chip patterns 81 are arranged, such that most number of chip patterns 81 are in the circular effective exposure region 83 that is a high resolution region.

A case will now be described in more detail, where the outer shape of the reticle pattern 82 is asymmetrical.

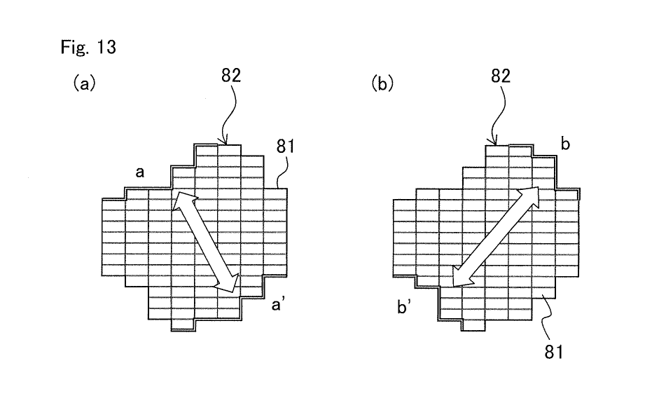

FIGS. 13(a) and 13(b) are explanatory diagrams for describing a case where the outer shape of the reticle pattern 82 is asymmetrical in a plane view.

As illustrated in FIG. 13(a), an outer shape a of the top left of the reticle pattern 82 matches an outer shape a′ of the bottom right. As illustrated in FIG. 13(b), an outer shape b of the top right of the reticle pattern 82 matches an outer shape b′ of bottom left. Specifically, the outer shape a on the top left of the reticle pattern 82 fits in without space to the outer shape a′ on the bottom right, and the outer shape bon the top right of the reticle pattern 82 also fits in without space to the outer shape b′ on the bottom left. Thereby, as illustrated in FIG. 12(b), when sequentially exposed, the top portion of the reticle pattern 82 fits in without space to the bottom position of reticle patterns 82 adjacent to each other to the left and right. Also in this case, ninety six chip patterns 81 are arranged for the outer shape of the reticle pattern 82 arranged to be inscribed in or without jutting out from the circle of the effective exposure region 83 to the maximum degree, in comparison to 6×14 or eighty four chip patters per shot for a quadrangular reticle pattern in a plane view.

Thus, in the exposure method of Embodiment 7, throughput is improved 96/84 times in comparison to the conventional exposure method. In this manner, utilizing the effective exposure region 83 in a most effective manner and improving throughput are made possible by increasing the number of chip patterns per shot and fitting in reticle patterns 82 with each other with no space without complicating the step feeding.

In the above-described Embodiment 7, a case has been described where the outer shape of the reticle pattern 82 is asymmetrical, and at the outer shape of the reticle pattern 82, the outer shapes of the arrangements of chip patterns 81 on the opposite angle sides fit in with each other, but is not limited to this. The outer shape of a reticle pattern may also be such that a plurality of chip patterns are arranged point-symmetrically. Specifically, when the outer shape of reticle pattern is point-symmetrical, the distance from the outer shape a on the top left to the center of the reticle pattern and the distance from the outer shape a′ on the bottom right to the center of the reticle pattern are equal, and the distance from the outer shape b on the top right of the reticle pattern to the center of the reticle pattern and the distance from the outer shape b′ on the bottom left to the center of the reticle pattern are equal. In this case, the outer shapes a and a′ and outer shapes b and b′

Also in this case, the outer shape a on the top left of the reticle pattern fits in without space to the outer shape a′ on the bottom right, and the outer shape b on the top right of the reticle pattern fits in without space to the outer shape b′ on the bottom left. Thereby, similarly to the case illustrated in FIG. 12(b), when sequentially exposed, the top part of the reticle pattern fits into the bottom position of reticle patterns adjacent to each other to the left and right. In this case, in the outer shape of the reticle pattern arranged to be inscribed in or without jutting out from the circle of the effective exposure region to the maximum degree, more chip patterns can be arranged in comparison to, for example, 6×14 or eighty four chip patterns per shot for a quadrangular shape in a plane view. As a specific example, the outer shapes of each of the reticle patterns of the above-described Embodiments 1 to 6 are point-symmetrical. When point-symmetrical, the outer shape of a reticle pattern can be such that the outer shape on the top right and that on the bottom left matches, and the outer shape on the top left and that on the bottom right matches and the outer shape on the top right and that of the top left matches, but is not limited to this. The outer shape of a reticle patter can also be such that the outer shape on the top right and that on the bottom left matches, and the outer shape on the top left and that on the bottom right matches and the outer shape on the top right and that on the top left are different.

In the above-described Embodiments 1 to 7, cases have been described where the high resolution region of a reduction exposure machine is utilized for maximum effectiveness. However, in addition, cases will be specifically described where reduction of number of chips can be minimized even if an evaluation pattern such as a test chip pattern TEG (test element group) is mounted on a wafer in next Embodiments 8 and 9

### Embodiment 8

In Embodiment 8, a case will be described where a test chip pattern TEG is used in place of one of a plurality of chip patterns 61 of a reticle for exposure 2D of FIG. 9 in a predetermined position. In a predetermined position of a plurality of chip patterns 61, a test chip pattern TEG is used in place of one chip pattern 61 on the left side of the bottom edge section.

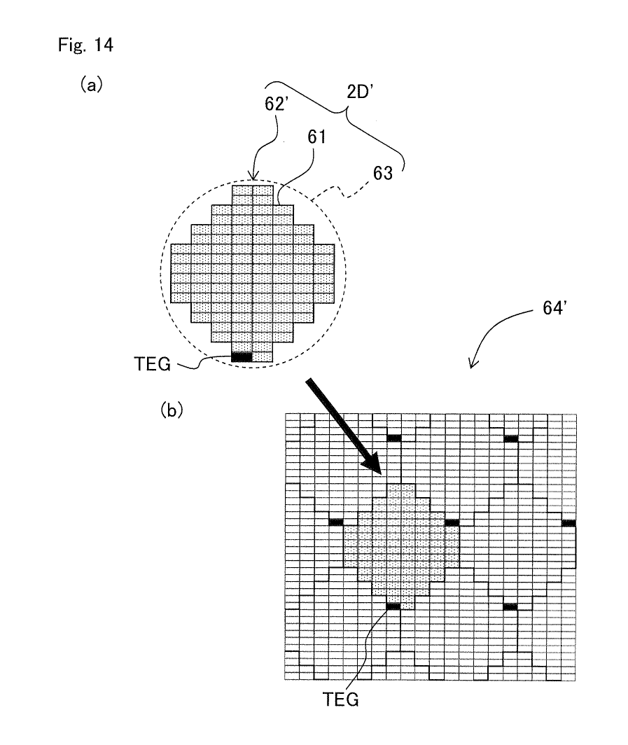

FIG. 14 is an explanatory diagram of Embodiment 8 of an exposure method using a test chip pattern for one of a plurality of chip patterns of the reticle for exposure 2D of FIG. 9. FIG. 14(a) is a plane view illustrating the relationship between a reticle pattern using a test chip pattern TEG and an effective exposure region. FIG. 14(b) is a diagram of sequential exposure patterns to a wafer 4.

In FIGS. 14(a) and 14(b), in the exposure method using a reticle for exposure 2D′ of Embodiment 8, reduced projection exposure is performed sequentially in the directions of length and width on a surface of a wafer 64′, on which a photo resist film is formed, using a reticle for exposure 2D′ formed such that a reticle pattern 62′ that is line-symmetrical to the top and bottom or left and right along a scribe line (mid line) between chip patterns having, for example, ninety five chip patterns 61 resulting from taking away each of twelve chip patters of the four corner sections from 8×18 or one hundred forty four chip patterns 61 and a test chip pattern TEG is inscribed in or does not jut out from the circle of the effective exposure region 63, which is a high resolution region. In this case, a test chip pattern TEG for inspection of an element and the like is disposed in a predetermined position among ninety six patterns. The number of patterns on the top and bottommost sides of ninety six patterns including the test chip pattern TEG is two each in the longitudinal direction, which is an even number, and the number on the left and right most sides is six each in the short end direction, which is an even number. When sequentially exposed, ninety six patterns including the test chip pattern TEG are sequentially arranged without space such that the top part of another reticle pattern 62′ fits into, with a half pitch offset, the bottom position of reticle patterns 62′ adjacent to each other to the left and right (width direction) without space.

A test chip pattern TEG is a chip for element inspection containing basic elements for monitoring production situation of elements of ninety five chip patterns 61. Quality of an element of chip patterns 61 can be determined by performing measurement inspection electrically on a basic element in the test chip pattern TEG made under the same production condition with the element of chip patterns 61. The basic element in the test chip pattern TEG is configured concisely, including the terminal structure, so that an inspection can be performed in a concise manner.

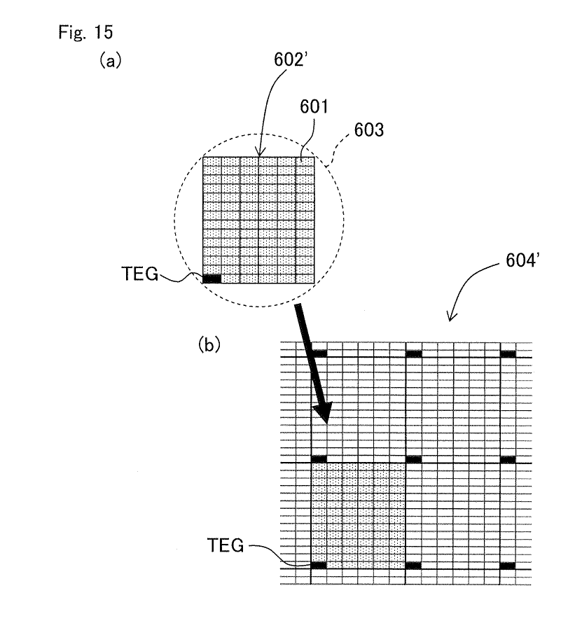

In the conventional exposure method, as a comparative example of FIG. 14, exposure on a reticle pattern 602′ constituted of eighty three chip patterns 601 with a rectangular shape in a plane view and a test chip pattern TEG on the bottom left corner section for a total of 6×14 eighty four patterns per shot, which is to be performed sequentially on a wafer 604′, is possible as illustrated in FIGS. 15(a) and FIGS. 15(b). In this case, the effective exposure region 603 of FIG. 15(a) and the effective exposure region 63 of FIG. 14(a) are circles with the same size. On the other hand, in the exposure method using the reticle for exposure 2D of Embodiment 8 illustrated in FIGS. 14(a) and 14(b), exposure of the reticle pattern 62′ constituted of ninety five chip patterns 61 and a test chip pattern TEG for a total of ninety six patterns per shot is possible. Thereby, in the exposure method of Embodiment 8, throughput is improved 95/83 times in comparison to the above-described conventional exposure method. In this manner, on the surface of the wafer 64′, utilizing the effective exposure region 63 in a most effective manner and improving throughput are made possible by increasing the number of chip patterns per shot and fitting in reticle patterns 62′ with each other with no space without complicating the step feeding.

### Embodiment 9

In the above-described Embodiment 8, a case has been described where one test chip pattern TEG is used, for example, for every reticle pattern 62 of FIG. 9. However, in Embodiment 9, a case will be described where a test chip pattern TEG is used for each one or several reticle patterns among a plurality of reticle patterns on the entire wafer in accordance with the position of the wafer.

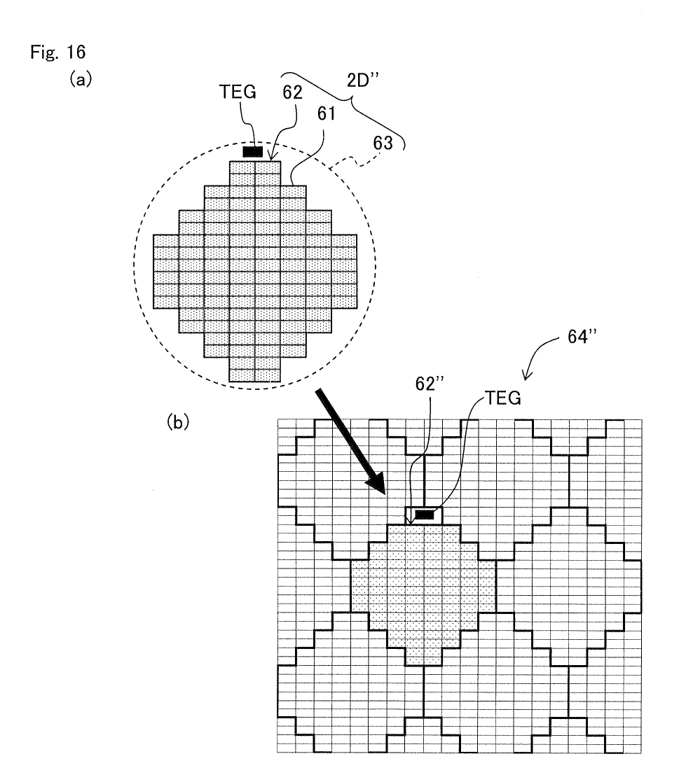

FIG. 16 is an explanatory diagram of Embodiment 9 of an exposure method using a test chip pattern on four chip pattern in the top edge section of a plurality of chip patterns of the reticle for exposure 2D of FIG. 9. FIG. 16(a) is a plane view illustrating the relationship between a reticle pattern using a test chip pattern TEG and an effective exposure region. FIG. 16(b) is a diagram of sequential exposure patterns to a wafer 4.

In FIGS. 16(a) and 16(b), in an exposure method using a reticle for exposure 2D′ of Embodiment 9, reduced projection exposure is performed sequentially in the directions of length and width on a surface of a wafer 64′, on which a photoresist film is formed, using a reticle for exposure 2D″formed such that a reticle pattern 62 that is line-symmetrical along a scribe line (midline) line) bisecting the reticle pattern to the top and bottom or left and right having, for example, ninety six chip patterns 61 resulting from taking away each of twelve chip patters of the four corner sections from 8×18 or one hundred forty four chip patterns 61 is inscribed in or does not jut out from the circle of the effective exposure region 63, which is a high resolution region. In this case, a test chip pattern TEG for inspection of an element and the like is exposed instead of a region of four chip patterns 61 on the top edge section among ninety six chip patterns 61. Here, in the reticle for exposure 2D″, a test chip pattern TEG is positioned to be exposed on the top side of the top most side of ninety six chip patterns 61 in the circle of the effective exposure region 63, which is a high resolution region, so that.

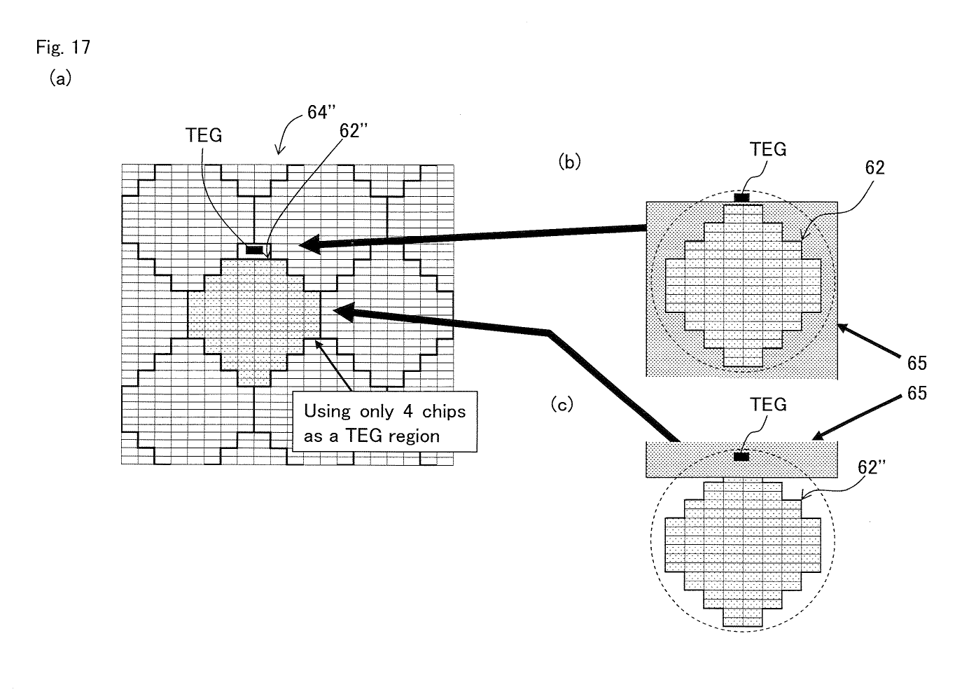

A test chip pattern TEG and ninety two reticle patterns 62″ are exposed with two shots. Specifically, after the test chip pattern TEG is exposed at a predetermined position by unshielding only the test chip pattern TEG while shielding all ninety six chip patterns shielded with the light shielding plate 65, as illustrated in FIG. 17(b), the test chip pattern TEG and the four chip patterns 61 on the top edge section among the ninety six chip pattern 61 is shielded from light with the light shield plate 65 to expose the reticle pattern 62″ constituted of the remaining ninety two chip patterns 61 on the bottom side to a predetermined position directly under the previously exposed test chip pattern TEG, as illustrated in FIG. 17(c). Alternatively, the order of exposure can be reversed. Specifically, after shielding the test chip pattern TEG and the four chip patterns 61 on the top edge section among the ninety six chip pattern 61 are shielded from light with the light shield plate 65 to expose the reticle pattern 62″ constituted of the remaining ninety two chip patterns 61 on the bottom side, as illustrated in FIG. 17(c), only the test chip pattern TEG is exposed at a predetermined position directly above the exposed reticle patterns 62″ by shielding all ninety six chip patterns 61 from light with the light shielding plate 65, as illustrated in FIG. 17(b). In other words, in this exposure method, the reticle patterns 62′ is exposed by shielding a part of the top side of the stair-like steps including the top edge part with a blind feature of a stepper (light shield plate 65) by using the reticle for exposure 2D″, and the test chip pattern TEG is exposed by unshielding the previously shielded region directly above the shielded region while shielding the reticle pattern 62″.

Thereby, as shown in FIG. 17(a), when sequentially exposed, the reticle patterns 62 and 62″ are sequentially arranged without space with the test chip pattern TEG included in the predetermined position on the wafer 64″ (center section and four peripheral sections thereof and the like) such that the top part of another reticle pattern 62 fits into, with a half pitch offset, the bottom position of reticle patterns 62 adjacent to each other to the left and right (width direction) without space.

A test chip pattern TEG is a chip pattern for element inspection containing a basic element for monitoring production situation of elements of a plurality of chip patterns 61 in the reticle patterns 62 and 62′ on the wafer 64″. Quality of an element of a plurality of chip patterns 61 can be determined by performing measurement inspection on a basic element in the test chip pattern TEG made under the same condition with the element of chip patterns 61. The basic element in the test chip pattern TEG is configured concisely, including the terminal structure, so that an inspection can be performed in a concise manner. The test chip pattern TEG of the above-described Embodiment 8 has a small-scale circuit configuration, and was thus used in place of a region of one chip pattern 61. However, since a test chip pattern TEG of Embodiment 9 has a large-scale circuit configuration, a region of four chip patterns 61 is used. Thus, the test chip pattern TEG is exposed and provided by a blind feature (light shield plate 65) separately from the ninety two chip patterns 61.

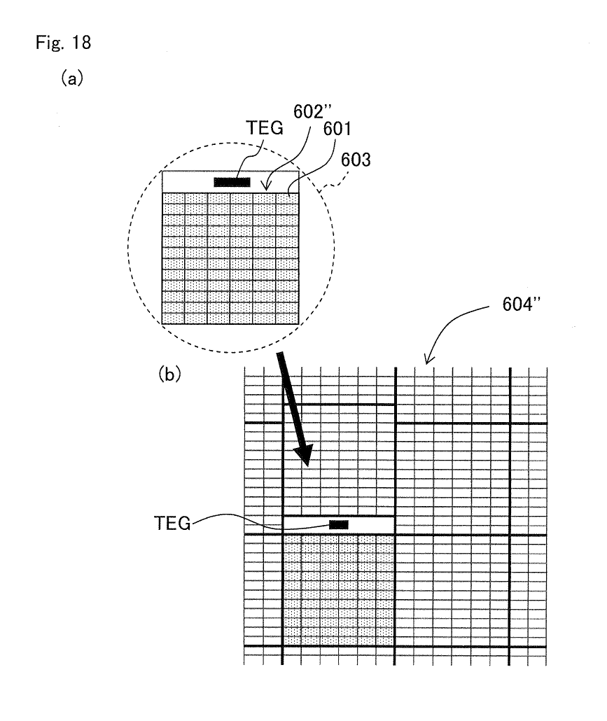

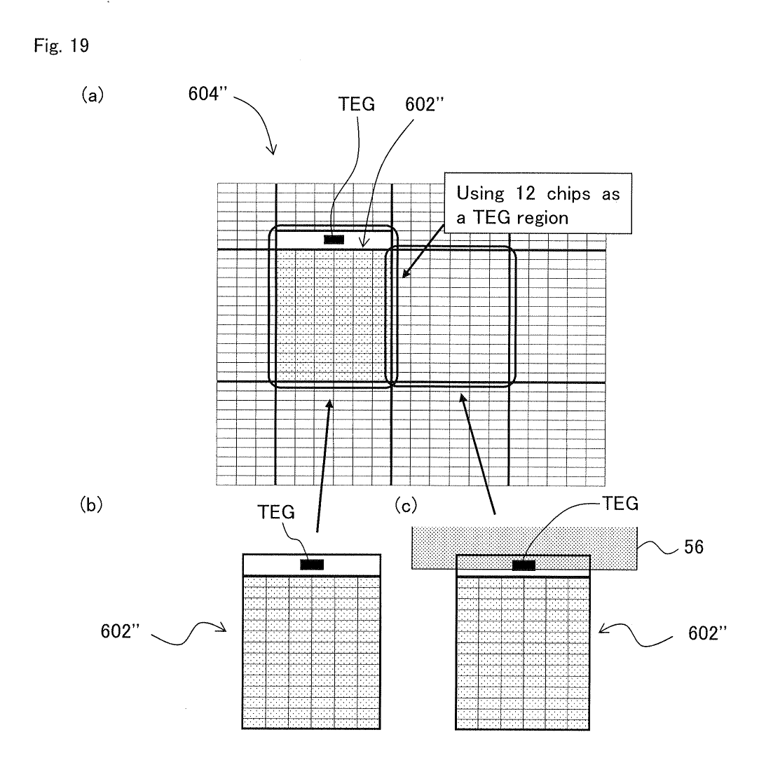

In the conventional exposure method, as shown in FIG. 18(a), 6×12 or seventy two chip patterns 601 with a rectangular shape in a plane view and a test chip pattern TEG in the top position thereof are accommodated in a circle of an effective exposure region 603, which is a high resolution region. Accordingly, a region of twelve chip patterns 601 is used to dispose a test chip pattern TEG. 6×12 or seventy two chip patterns 601 per shot with a rectangular shape in a plane view that are sequentially exposed on a wafer 604″ are sequentially exposed while the test chip pattern TEG is shielded with a light shield plate 56, as illustrated in FIG. 19(c). In a case where one test chip pattern TEG is exposed, as illustrated in FIG. 19(b), the light shield plate 56 is completely removed to expose the test chip pattern TEG and seventy two chip patterns 601 therebelow, and as shown in FIGS. 18(b) and 19(a), the reticle pattern 602″ is sequentially arranged without space with the test chip pattern TEG included in the predetermined position of the wafer 604″ (center section of the wafer and four peripheral sections thereof and the like). Furthermore, in the conventional exposure method, as shown in FIGS. 18(b) and 19(a), step feeding involves a difference in step for the amount of a region for exposing one test chip pattern TEG, and thus is made complicated.

In contrast, in the exposure method using the reticle for exposure 2D″ of Embodiment 9 illustrated in FIGS. 16(a) and 16(b), exposure of the reticle pattern 62″ constituted of ninety two chip patterns 61 and a test chip pattern TEG per shot is possible, even when there is a test chip pattern TEG. Thereby, in the exposure method of Embodiment 9, throughput is further improved 92/72 times in comparison to the conventional exposure method.

From the above, accordingly to Embodiment 9, even when using a test chip pattern TEG, on the surface of wafer 64″, utilizing the effective exposure region 63 in a most effective manner and further improving throughput are possible by increasing the number of chip patterns per shot and fitting in reticle patterns 62″ with each other with no space without complicating the step feeding.

Although not specifically described in the above-described Embodiment 8, when the conventional exposure method with respect to the above-described Embodiment 9 is compared to the reticle pattern of the above-described Embodiment 8, throughput can be further improved.

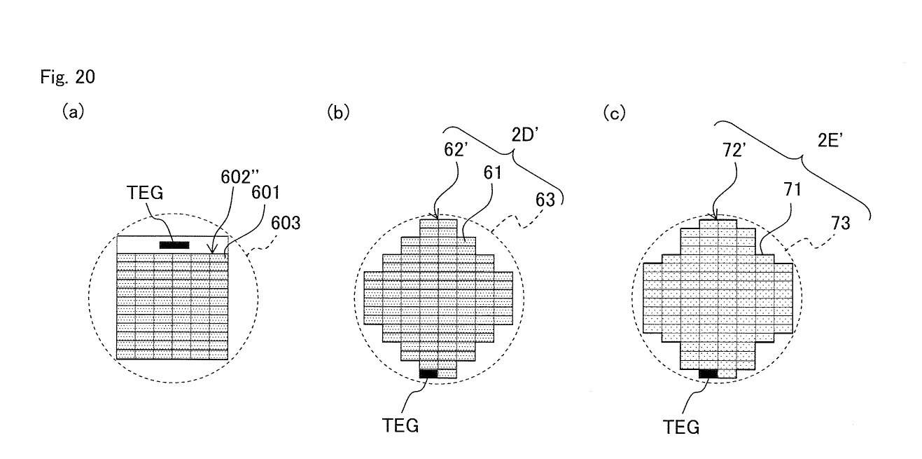

FIG. 20(a) is a plane view illustrating the relationship between a reticle pattern per shot by a conventional exposure method with respect to the above-described Embodiment 9 and an effective exposure region. FIG. 20(b) is a plane view illustrating the relationship between the reticle pattern of the above-described Embodiment 8 and an effective exposure region. FIG. 20(c) is a plane view illustrating the relationship between a case where a test chip pattern TEG is used as one of a plurality of chip patterns in the modified example of the reticle pattern of the above-described Embodiment 6 and an effective exposure region.

When a test chip pattern TEG is used, in the conventional exposure method, as shown in FIG. 20(a), exposure of the rectangular reticle pattern in a plane view constituted of 6×12 or seventy two chip patterns 601 per shot is possible. However, in the exposure method using the reticle for exposure 2D′ of the above-described Embodiment 8 illustrated in FIG. 20(b), exposure of the reticle pattern 62′ constituted of ninety five chip patterns 61 per shot is possible. Thereby, in the exposure method of Embodiment 8, throughput is further improved 95/72 times in comparison to the conventional exposure method.

When a test chip pattern TEG is used as one of ninety six chip patterns 71 in the modified example of the reticle pattern of the above-described Embodiment 6 illustrated in FIG. 20(c), in an exposure method using a reticle for exposure 2E′, exposure of a reticle pattern 72′ constituted of ninety five chip patterns 71 per shot is possible. Thereby, in the exposure method where a test chip pattern TEG is used as one of ninety six chip patterns 71 in the modified example of the reticle pattern of the above-described Embodiment 6, throughput is further improved 95/72 times in comparison to the conventional exposure method.

According to the above Embodiments 8 and 9, a writing area of a reticle for exposure can be used effectively (number of chip patterns on a reticle pattern can be increased) by using a reticle for exposure in which chip patterns of the outer shape of a reticle are arranged in a stair-like shape. Even when a test chip pattern TEG is incorporated into an LSI chip region as in the above-described Embodiment 8, exposure can be performed in the same way. Even when another test chip pattern TEG is used as in the above-described Embodiment 9, exposure of the test chip pattern TEG is made possible by shielding a part of light with a blind feature of a stepper.

Accordingly, even when a test chip pattern TEG is built in place of a chip pattern as in the above-described Embodiment 8, throughput can be improved by reducing the number of shots for an entire wafer from increasing the number of chips on a reticle pattern, and the number of chip patterns on a reticle pattern can be improved from decreasing the number of test chip pattern TEG. Further, even when a test chip pattern TEG is separately arranged as in the above-described Embodiment 9, the number of chip patterns on the reticle pattern is improved, as necessary number of test chip pattern TEG can be arranged and the region is minimized by the arrangement. The region of a test chip pattern TEG secured can be made to be a minimum region needed for a test chip pattern TEG by using the top end section of outer shape of the chip patterns arranged in a stair-like shape.

The tendency of an element from the center section to the peripheral section of a wafer can be analyzed in more detail in case where one or a plurality of test chip pattern TEG is disposed in a reticle pattern for every reticle pattern as in the above-described Embodiment 8, in comparison to the case where one or several test chip pattern TEG is disposed on a wafer outside of a reticle pattern as in the above-described Embodiment 9. Further, when there is little variation in the elements for a product, greater number of chip patterns can be arranged in a case where one or several test chip pattern TEG is disposed on a wafer apart from a reticle pattern as in the above-described Embodiment 9 than in a case where one or a plurality of test chip pattern TEG is disposed in a reticle pattern for every reticle pattern as in the above-described Embodiment 8. Thus, the number of test chip pattern TEGs for a wafer is set in accordance with variation in product performance. Further, in a case where one or a plurality of test chip pattern TEG is disposed in a reticle pattern for every reticle pattern as in the above-described Embodiment 8, inspection points can be suitably changed in accordance with the production situation of a product chip.

It is preferable that the region of a test chip pattern TEG is contained within a region of one chip pattern as in the above-described Embodiment 8. However, when a larger region is required, a test chip pattern TEG is disposed in a region in the top edge section or/and bottom edge section of a reticle pattern as in the above-described Embodiment 9 (four chip patterns of the top edge section in the above-described Embodiment 9). In the above-described Embodiments 1 to 9, the outer shape of the reticle patterns are formed in balanced or imbalanced stair-like shapes of shots and a plurality of chip patterns are arranged. Since the light shield plate 65 shields a region of a test chip pattern TEG from light from top and bottom or left and right direction, a region in the top edge section or the bottom edge section of a reticle pattern can be set to be a region with appropriate size as much as possible and throughput can be improved for reticle patterns in which a tip section gradually narrows as in a stair-like shape of a shot. In other words, although a test chip pattern TEG can be disposed in any position of a reticle pattern, in a case where a region of a test chip pattern TEG is greater than a size of a chip pattern, since the light shield plate 65 or 56 shields a light from top and bottom or left and right direction for exposure of a test chip pattern TEG which leads to using more chip patterns than is required for exposure of a test chip pattern TEG, it is sufficient to arrange a plurality of chip patters as the outer shape of a reticle pattern is formed in a uniform or uneven stair-like shape of a shot while the region of the test chip pattern TEG comprises at least one of the left edge section, right edge section, top edge section, or bottom edge section, so that minimum amount of region is required for exposure of the test chip pattern TEG.

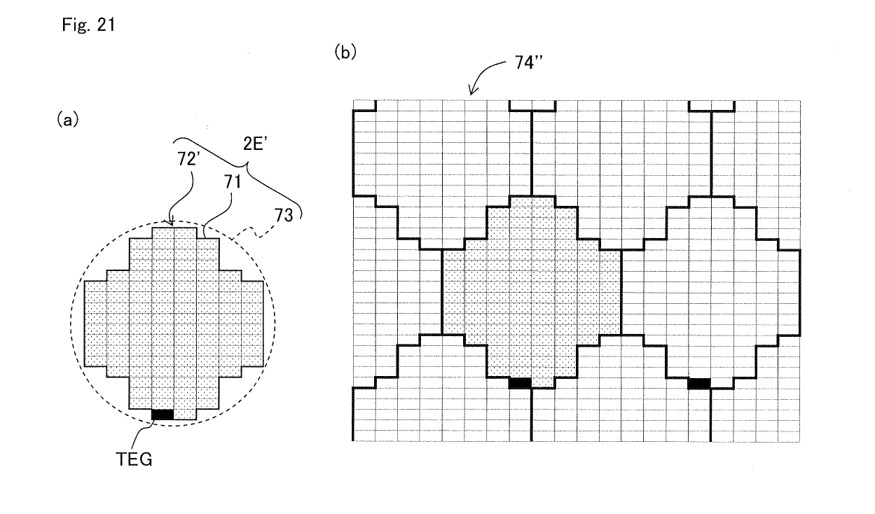

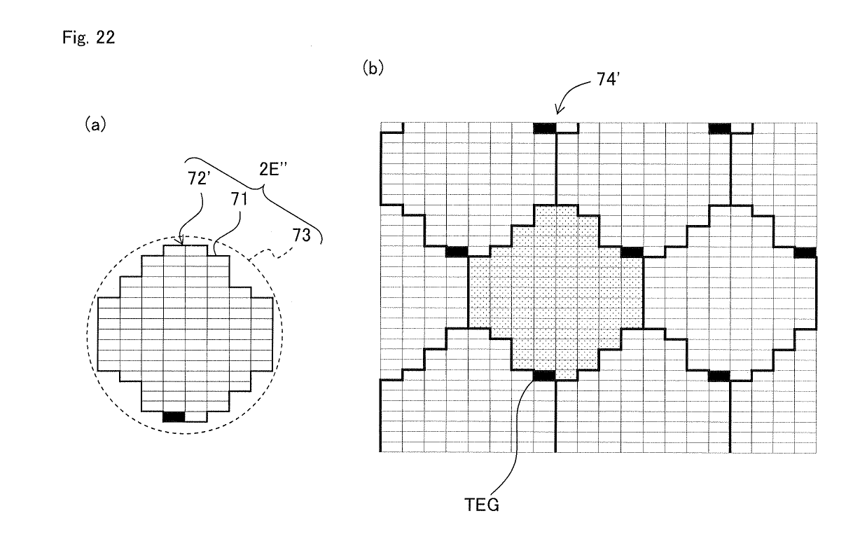

In the above-described Embodiment 8, a case has been described where a test chip pattern TEG is used in place of one chip pattern in the reticle for exposure 2D of the above-described Embodiment 5 of FIG. 9, but is not limited to this. a test chip pattern TEG of the above-described Embodiment 8 can be used in place of a chip pattern in the reticle for exposure 2E of the above-described Embodiment 6 of FIG. 10, and reticle for exposure 2E′ of FIG. 21 and reticle for exposure 2E″ of FIG. 22 corresponding thereto, by which throughput is improved in comparison to the conventional reticle pattern with a quadrangular outer shape. Similarly, in the above-described Embodiment 9, use of a test chip pattern TEG in place of four chip patterns in the top edge section of reticle for exposure 2D of the above-described Embodiment 5 of FIG. 9 has been described, but is not limited to this. A test chip pattern TEG of the above-described Embodiment can be used in place of two chip patterns in the top edge section or the bottom edge section in the reticle for exposure 2E of the above-described Embodiment 6 of FIG. 10, and a reticle for exposure 2E′ of FIG. 21 and a reticle for exposure 2E″, which is asymmetrical to the left and right, of FIG. 22, which are modified examples thereof, and throughput can be improved in comparison to the reticle pattern of the conventional exposure method with a conventional quadrangular outer shape.

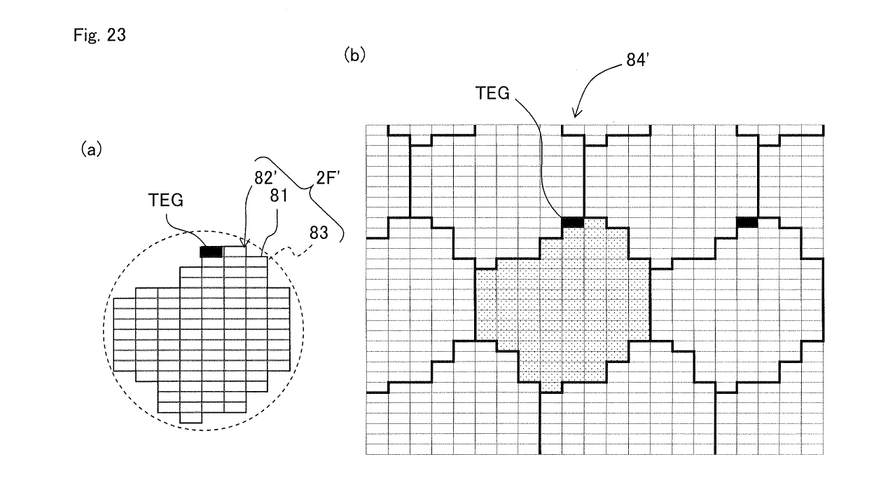

In the above-described Embodiment 8, a case has been described where a test chip pattern TEG is used in place of one chip pattern in the reticle for exposure 2D of the above-described Embodiment 5 of FIG. 9, but is not limited to this. A test chip pattern TEG of the above-described Embodiment 8 can be used in place of a chip pattern in a reticle for exposure 2F′ of FIG. 23 corresponding to the reticle for exposure 2F of FIG. 12 and throughput is improved in comparison to the conventional reticle pattern with a quadrangular outer shape. Similarly, in the above-described Embodiment 9 using a test chip pattern TEG in place of four chip patterns in the top edge section of reticle for exposure 2D of the above-described Embodiment 5 of FIG. 9 has been described, but is not limited to this. A test chip pattern TEG of the above-described Embodiment 9 can be used in place of two chip patterns in the top edge in the reticle for exposure 2F of FIG. 12 and throughput is improved in comparison to the reticle pattern of the conventional exposure method with a conventional quadrangular outer shape.

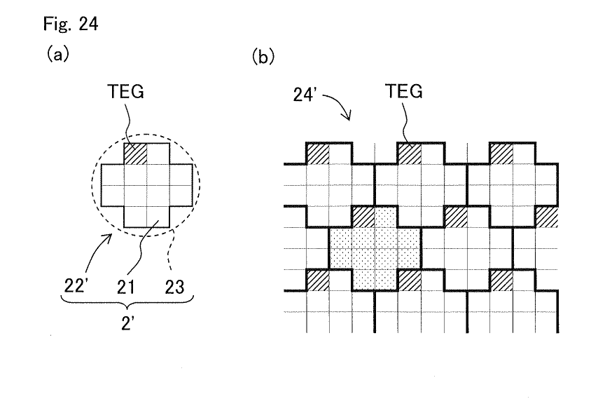

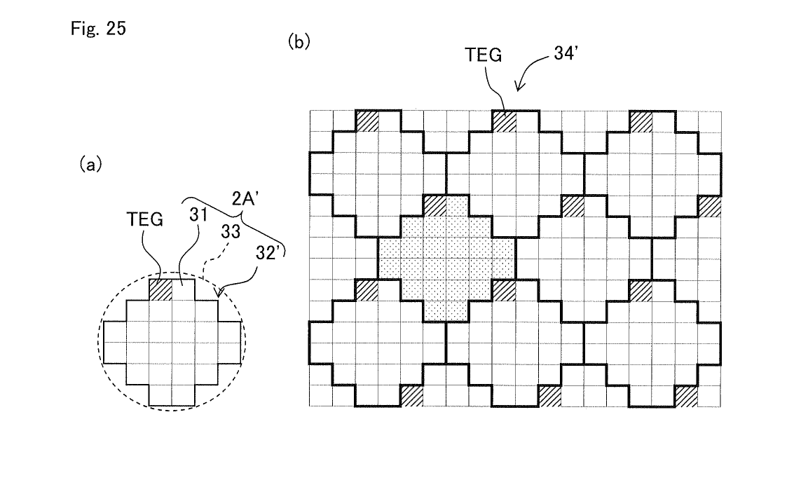

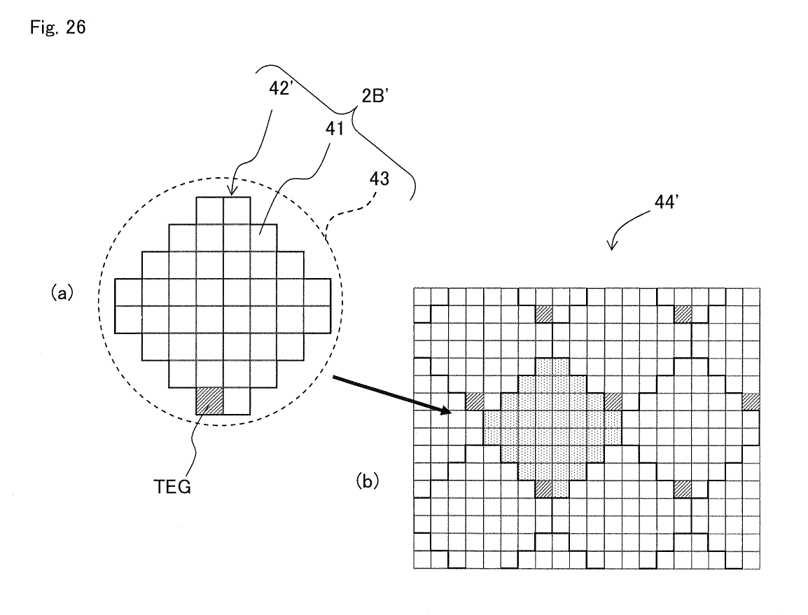

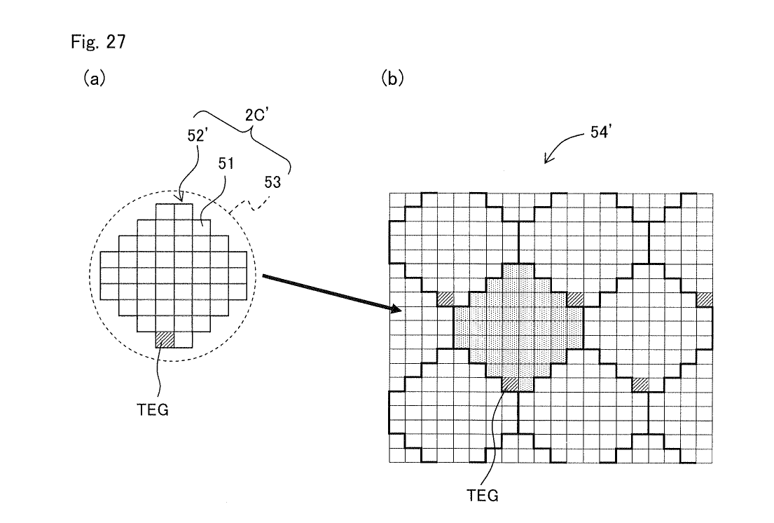

In the above-described Embodiment 8, using a test chip pattern TEG in place of a chip pattern in the reticle for exposure 2D of the above-described Embodiment 5 of FIG. 9 has been described, but is not limited to this. A test chip pattern TEG of the above-described Embodiment 8 can be used in place of a chip pattern in reticles 2′, 2A′, 2B′, and 2C′ of FIGS. 24 to 27, which are modified examples of reticle for exposure 2′, 2A′, 2B′, and 2C′ of the above-described Embodiments 1 to 4 of FIGS. 2, 4, 6, and 8, and throughput is improved in comparison to the conventional reticle pattern with a quadrangular outer shape. Similarly, in the above-described Embodiment 9 using a test chip pattern TEG in place of four chip patterns in the top edge section of reticle for exposure 2D of the above-described Embodiment 5 of FIG. 9 has been described, but is not limited to this. A test chip pattern TEG for electronic verification of the above-described Embodiment 9 can be used in place of two chip patterns in the top edge section or the bottom edge section in the reticle for exposures 2′, 2A′, 2B′, and 2C′ of FIGS. 24 to 27, which correspond to reticle for exposure 2F of the above-described Embodiments 1 to 4 of FIGS. 2, 4, 6, and 8, and throughput is improved in comparison to the reticle pattern of the conventional exposure method with a conventional quadrangular outer shape.

In the above-described Embodiments 8 and 9, a test chip pattern TEG (monitoring chip pattern) for electronic verification is disposed in place of a part of a chip pattern region, but is not limited to this. A pattern for alignment (alignment mark) or a mark for measuring (a pattern for shape inspection when a film is superposed) may be disposed in place of a part of a chip pattern region. An evaluation pattern is configured by the test chip pattern TEG for element inspection, and a pattern for alignment, and a pattern for shape inspection. Thus, an evaluation pattern is either a test chip pattern TEG, a pattern for alignment, or a pattern for dimension inspection of shape, length, and the like.

In other words, one or a plurality of evaluation patterns are disposed in place of a region of one or a plurality of chip patterns constituting a reticle pattern. Further, one or a plurality of evaluation patterns are disposed inside and outside of an exposure region of a reticle pattern. One or a plurality of evaluation patterns are disposed in a chip pattern region including at least one of the left edge section, right edge section, top edge section, or the bottom edge section of the outer shape of a reticle that has a uniform or uneven stair-like shape.

As described above, the present invention is exemplified by the use of its preferred Embodiments 1 to 9 of the present invention. However, the present invention should not be interpreted solely based on Embodiments 1 to 9 described above. It is understood that the scope of the present invention should be interpreted solely based on the scope of the claims. It is also understood that those skilled in the art can implement equivalent scope of technology, based on the description of the present invention and common knowledge from the description of the detailed preferred Embodiments 1 to 9 of the present invention. Furthermore, it is understood that any patent, any patent application and any references cited in the present specification should be incorporated by reference in the present specification in the same manner as the contents are specifically described therein.

### INDUSTRIAL APPLICABILITY

The present invention can be applied in the field of a reticle for exposure that is used for a stepper apparatus and the like as a reduced projection exposure apparatus for use in production of a semiconductor apparatus such as a semiconductor integrated circuit (IC, LSI, and the like), light-emitting apparatus such as LED and laser, or a solid-state imaging element; an exposure method of exposure using said reticle for exposure; and a production method of a semiconductor wafer for producing a plurality of semiconductor apparatuses using said exposure method. According to the present invention as described above, since a reticle pattern has an outer shape of a reticle pattern arranged to the maximum degree has a greater number of chip patterns in comparison to the number of chip patterns with a quadrangular shape in a plane view is inscribed in or does not jut out from a circle of an effective exposure region When sequentially exposed, forty eight chip patterns are arranged such that the top part of another reticle pattern 52 fits into, with a half pitch offset, the bottom position of reticle patterns adjacent to each other without space. Utilizing the effective exposure region in a most effective manner and improving throughput are made possible by increasing the number of chip patterns per shot and fitting in reticle patterns with each other with no space without complicating the step feeding.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

### REFERENCE SIGNS LIST

1 floodlight apparatus
2, 2A to 2F, 2A′ to 2F′, 2D″, 2E″ reticle for exposure (photomask)
3 reduced projection apparatus
4 wafer (substrate)
5 table
10 stepper apparatus (reduced projection exposure apparatus)
21, 31, 41, 51, 61, 71, 81 chip patterns
22, 32, 42, 52, 62, 72, 82, 22′, 32′, 42′, 52′, 62′, 72′, 82′, 62″, 72″ reticle pattern
23, 33, 43, 53, 63, 73, 83 effective exposure region
24, 34, 44, 54, 64, 74, 84, 24′, 34′, 44′, 54′, 64′,
74′, 84′, 64″, 74″ wafer (substrate)
56, 65 light shield plate TEG test chip pattern
301, 401, 501, 601 chip pattern
302, 402, 502, 602, 602′, 602″ reticle pattern
303, 403, 503, 603 effective exposure region
304, 404, 504, 604′, 604″ wafer (substrate)

What is claimed is:

1. A reticle for exposure containing a reticle pattern constituted of a plurality of chip patterns in a circular effective exposure region of a reduced projection exposure apparatus, wherein
the reticle pattern has an outer shape arranged to be inscribed in or without jutting out from the circle of the effective exposure region with a greater number of chip patterns in comparison to the number of chip patterns in a quadrangular shape in a plane view, and when sequentially exposed, the plurality of chip patterns are arranged such that a top part of the reticle pattern fits in without space to a bottom position of the reticle patterns adjacent to each other to the left and right.

2. A reticle for exposure according to claim 1, wherein the outer shape of the reticle pattern has the plurality of chip patterns arranged in a stair-like shape of a shot with uniform steps or uneven steps, such that the outer shape of the reticle pattern is inscribed in or does not jut out from the circle of the effective exposure region.

3. A reticle for exposure according to claim 1, wherein the outer shape of the reticle pattern has the plurality of chip patterns arranged line-symmetrically top and bottom or left and right in a plane view with respect to a mid line along a scribe line between the chip patterns.

4. A reticle for exposure according to claim 1, wherein the outer shape of the reticle pattern has the plurality of chip patterns arranged line-symmetrically top and bottom and left and right in a plane view with respect to amid line along a scribe line between the chip patterns.

5. A reticle for exposure according to claim 1, wherein the outer shape of the reticle pattern has the plurality of chip patterns arranged point-symmetrically.

6. A reticle for exposure according to claim 1, wherein the outer shape of the reticle pattern has the plurality of chip patterns arranged asymmetrically.

7. A reticle for exposure according to claim 1, wherein one side of a quadrangular shape in a plane view of the chip patterns and another side adjacent thereto are equal or different.

8. A reticle for exposure according to claim 1, wherein when m and n are both integers greater than or equal to four, the reticle pattern has a plurality of chip patterns resulting from taking away chip patterns of four corners from a plurality of chip patterns with an m×n quadrangular shape.

9. A reticle for exposure according to claim 1, wherein when m and n are both integers greater than or equal to two, the reticle pattern has an even number of chip patterns protruding out to the top and bottom or/and the left and right from the entire side or from each center section of four sides of chip patterns with an m×n quadrangular shape.

10. A reticle for exposure according to claim 8, wherein when m and n are both four, the reticle pattern has twelve chip patterns resulting from taking away chip patterns of four corners from 4×4 or sixteen chip patterns.

11. A reticle for exposure according to claim 9, wherein when m and n are both two, the reticle pattern has chip patterns protruding out from the entire side of four sides of a reticle pattern constituted of 2×2 or four chip patterns, with two chip patterns each protruding out to the top and bottom and two chip patterns each protruding out to the left and right.

12. A reticle for exposure according to claim 1, wherein when m and n are both integers greater than or equal to six, the reticle pattern has a plurality of chip patterns resulting from taking away one or a plurality of chip patterns in four corners and those adjacent to the four corners from a plurality of chip patterns with an m×n quadrangular shape.

13. A reticle for exposure according to claim 12, wherein when m and n are both six, the reticle pattern has twenty-four chip patterns resulting from taking away each of three chip patterns in four corners and in four corner sections adjacent to the four corners from 6×6 or thirty six chip patterns.

14. A reticle for exposure according to claim 9, wherein when m and n are both four, the reticle pattern has chip patterns protruding out from each center section of four sides of a reticle pattern constituted of 4×4 or sixteen chip patterns, with two chip patterns each protruding out from the top and bottom and two chip patterns each protruding out from the left and right.

15. A reticle for exposure according to claim 1, wherein when m and n are both integers greater than or equal to eight, the reticle pattern has a plurality of chip patterns resulting from taking away each chip patterns of four corner sections, in four corners and one or a plurality of consecutive chip patterns adjacent the four corners inside and on the outer circumference, from a plurality of chip patterns with an m×n quadrangular shape such that the reticle pattern is inscribed in or does not jut out from the circle in the effective exposure region.

16. A reticle for exposure according to claim 1, wherein when m and n are both integers greater than or equal to six, the reticle pattern has one or a plurality of chip patterns taken away in the up and down directions in four corners of chip patterns with an m×n quadrangular shape and has an even number of chip patterns protruding out to the top and bottom or/and left and right from each center section of four sides of chip patterns with the m×n quadrangular shape, such that the reticle pattern is inscribed in or does not jut out from the circle of the effective exposure region.

17. A reticle for exposure according to claim 15, wherein when m and n are both eight, the reticle pattern has forty chip patterns resulting from taking away each six chip patterns of four corner sections, in four corners and one or a plurality of consecutive chip patterns adjacent the four corners inside and on the outer circumference, from 8×8 or sixty four chip patterns.

18. A reticle for exposure according to claim 16, wherein when m and n are both six, the reticle pattern has each chip pattern of four corners taken away from a reticle pattern constituted of 6×6 or thirty-six chip patterns and chip patterns protrude out from each center section of four sides of the reticle pattern constituted of the 6×6 or thirty-six chip patterns, with two chip patterns each protruding out to the top and bottom and two chip patterns each protruding out to the left and right.

19. A reticle for exposure according to claim 15, wherein when m is eight and n is nine, the reticle pattern has forty-eight chip patterns resulting from taking away each six chip patterns of four corner sections, in four corners and one or a plurality of consecutive chip patterns adjacent the four corners inside and on the outer circumference, from 8×9 or seventy-two chip patterns.

20. A reticle for exposure according to claim 16, wherein when m is six and n is seven, the reticle pattern has each chip pattern in four corners taken away from a reticle pattern constituted of 6×7 or forty-two chip patterns and chip patterns protrude out from each center section of four sides of the reticle pattern constituted of 6×7 or forty-two chip patterns, with two chip patterns each protruding out from the top and bottom and three chip patterns each protruding out to the left and right.

21. A reticle for exposure according to claim 15, wherein when m is eight and n is eighteen, the reticle pattern has ninety-six chip patterns resulting from taking away twelve chip patterns each of four corner sections, in four corners and one or a plurality of consecutive chip patterns adjacent the four corners inside and on the outer circumference, from 8×18 or one-hundred-forty-four chip patterns.

22. A reticle for exposure according to claim 16, wherein when m is six and n is fourteen, the reticle pattern has two chip patterns each consecutively in the up and down direction of four corners taken away from a reticle pattern constituted of 6×14 or eighty-four chip patterns and chip patterns protruding out from each center section of four sides of the reticle constituted of the 6×14 or eighty-four chip patterns, with two chip patterns with a width of two for a total of four chip patterns each protruding out to the top and bottom, and six chip patterns each protruding out to the left and right.

23. A reticle for exposure according to claim 15, wherein when m is eight and n is seventeen or eighteen, the reticle pattern has ninety-six or one-hundred-four chip patterns resulting from taking away each ten chip patterns of four corner sections, in four corners and one or a plurality of consecutive chip patterns adjacent the four corners inside and on the outer circumference, from 8×17 or 8×18, or one-hundred-thirty-six or one-hundred-forty-four chip patterns.

24. A reticle for exposure according to claim 16, wherein when m is six and n is fourteen, the reticle pattern has three chip patterns consecutively in the up and down directions in each of the up and down directions of four corners taken away from a reticle pattern constituted of 6×15 or 6×16, or ninety or ninety-six chip patterns and chip patterns protrude out from each center section of four sides of the reticle pattern constituted of 6×15 or 6×16, or ninety or ninety-six chip patterns, with two chip patterns each protruding out to the top and bottom, and seven or eight chip patterns each protruding out to the left and right.

25. A reticle for exposure according to claim 1, wherein one or a plurality of evaluation patterns are disposed in place of a region of one or a plurality of chip patterns constituting the reticle pattern.

26. A reticle for exposure according to claim 1, wherein one or a plurality of evaluation patterns are disposed inside or outside of an exposure region of the reticle pattern.

27. A reticle for exposure according to claim 25, wherein the outer shape of the reticle pattern has a uniform or uneven stair-like shape, and the one or the plurality of evaluation patterns are disposed in a region of chip patterns comprising at least one of a left edge section, a right edge section, a top edge section, or a bottom edge section of the reticle pattern.

28. A reticle for exposure according to claim 26, wherein the outer shape of the reticle pattern has a uniform or uneven stair-like shape, and the one or the plurality of evaluation patterns are disposed in a region of chip patterns comprising at least one of a left edge section, a right edge section, a top edge section, or a bottom edge section of the reticle pattern.

29. A reticle for exposure according to claim 25, wherein the evaluation pattern is one of a test chip pattern, an alignment pattern, or a pattern for inspection of dimension.

30. A reticle for exposure according to claim 26, wherein the evaluation pattern is one of a test chip pattern, an alignment pattern, or a pattern for inspection of dimension.

31. An exposure method for repeatedly reduce-exposing adjacent a scribe line on a wafer on which a photoresist film is formed, using a reticle for exposure according to claim 1, such that the reticle patterns fit in with each other without space and the scribe line is positioned between the chip patterns.

32. An exposure method according to claim 31, the method using a reticle for exposure provided with the evaluation pattern outside of an exposure region of the reticle pattern and comprising the steps of:
shielding a part of a stair-like step section including a top edge part or a bottom edge part of the reticle pattern with a blind function of a stepper to expose the rest of the reticle pattern; and
shielding all of the reticle pattern with the blind function of the stepper to expose the evaluation pattern to be adjacent the exposed reticle pattern.

33. An exposure method according to claim 31, the method using a reticle for exposure provided with the evaluation pattern outside of an exposure region of the reticle pattern and comprising the steps of:
shielding the reticle pattern with a light shield plate to expose only the evaluation pattern on a predetermined position of a wafer; and
shielding the evaluation pattern and an entire region of chip patterns including at least one of a left edge section, a right edge section, a top edge section, or a bottom edge section adjacent to the evaluation pattern with the light shield plate to expose the rest of the reticle pattern on a predetermined position adjacent to the previously exposed evaluation pattern.

34. An exposure method according to claim 31, the method using a reticle for exposure provided with the evaluation pattern outside of an exposure region of the reticle pattern and comprising the steps of:
shielding the evaluation pattern and the entire region of chip patterns including at least one of the left edge section, the right edge section, the top edge section, or the bottom edge section adjacent to the evaluation pattern with the light shield plate to expose the rest of reticle patterns; and
unshielding only the evaluation pattern with the light shield plate to expose the evaluation pattern to chip patterns for the evaluation pattern.

35. An exposure method for repeatedly reduce-exposing adjacent a scribe line on a wafer on which a photoresist film is formed, using a reticle for exposure according to claim 25, such that the reticle patterns fit in with each other without space and the scribe line is positioned between the chip patterns.

36. An exposure method according to claim 35, the method using a reticle for exposure provided with the evaluation pattern outside of an exposure region of the reticle pattern and comprising the steps of:
shielding a part of a stair-like step section including a top edge part or a bottom edge part of the reticle pattern with a blind function of a stepper to expose the rest of the reticle pattern; and
shielding all of the reticle pattern with the blind function of the stepper to expose the evaluation pattern to be adjacent the exposed reticle pattern.

37. An exposure method according to claim 35, the method using a reticle for exposure provided with the evaluation pattern outside of an exposure region of the reticle pattern and comprising the steps of:
shielding the reticle pattern with a light shield plate to expose only the evaluation pattern on a predetermined position of a wafer; and
shielding the evaluation pattern and an entire region of chip patterns including at least one of a left edge section, a right edge section, a top edge section, or a bottom edge section adjacent to the evaluation pattern with the light shield plate to expose the rest of the reticle pattern on a predetermined position adjacent to the previously exposed evaluation pattern.

38. An exposure method according to claim 35, the method using a reticle for exposure provided with the evaluation pattern outside of an exposure region of the reticle pattern and comprising the steps of:
shielding the evaluation pattern and the entire region of chip patterns including at least one of the left edge section, the right edge section, the top edge section, or the bottom edge section adjacent to the evaluation pattern with the light shield plate to expose the rest of reticle patterns; and
unshielding only the evaluation pattern with the light shield plate to expose the evaluation pattern to chip patterns for the evaluation pattern.

39. An exposure method for repeatedly reduce-exposing adjacent a scribe line on a wafer on which a photoresist film is formed, using a reticle for exposure according to claim 26, such that the reticle patterns fit in with each other without space and the scribe line is positioned between the chip patterns.

40. An exposure method according to claim 39, the method using a reticle for exposure provided with the evaluation pattern outside of an exposure region of the reticle pattern and comprising the steps of:
shielding a part of a stair-like step section including a top edge part or a bottom edge part of the reticle pattern with a blind function of a stepper to expose the rest of the reticle pattern; and
shielding all of the reticle pattern with the blind function of the stepper to expose the evaluation pattern to be adjacent the exposed reticle pattern.

41. An exposure method according to claim 39, the method using a reticle for exposure provided with the evaluation pattern outside of an exposure region of the reticle pattern and comprising the steps of:
shielding the reticle pattern with a light shield plate to expose only the evaluation pattern on a predetermined position of a wafer; and
shielding the evaluation pattern and an entire region of chip patterns including at least one of a left edge section, a right edge section, a top edge section, or a bottom edge section adjacent to the evaluation pattern with the light shield plate to expose the rest of the reticle pattern on a predetermined position adjacent to the previously exposed evaluation pattern.

42. An exposure method according to claim 39, the method using a reticle for exposure provided with the evaluation pattern outside of an exposure region of the reticle pattern and comprising the steps of:
shielding the evaluation pattern and the entire region of chip patterns including at least one of the left edge section, the right edge section, the top edge section, or the bottom edge section adjacent to the evaluation pattern with the light shield plate to expose the rest of reticle patterns; and
unshielding only the evaluation pattern with the light shield plate to expose the evaluation pattern to chip patterns for the evaluation pattern.

43. A production method of a semiconductor wafer for producing a plurality of semiconductor elements by pattering the photoresist film using the exposure method according to claim 31 to form each layer by using the patterned photoresist film as a mask.

44. A production method of a semiconductor wafer for producing a plurality of semiconductor elements by pattering the photoresist film using the exposure method according to claim 35 to form each layer by using the patterned photoresist film as a mask.

45. A production method of a semiconductor wafer for producing a plurality of semiconductor elements by pattering the photoresist film using the exposure method according to claim 39 to form each layer by using the patterned photoresist film as a mask.
